(19) United States
(12) Patent Application Publication
(10) Pub. No.: US 2023/0247834 A1
(43) Pub. Date: Aug. 3, 2023

(54) THREE-DIMENSIONAL SEMICONDUCTOR MEMORY DEVICE, ELECTRONIC SYSTEM INCLUDING THE SAME, AND METHOD OF FABRICATING THE SAME

(71) Applicant: Samsung Electronics Co., Ltd., Suwon-si (KR)

(72) Inventors: Soyeong AHN, Uiwang-si (KR); Gukhyon YON, Yongin-si (KR)

(73) Assignee: Samsung Electronics Co., Ltd., Suwon-si (KR)

(21) Appl. No.: 17/986,983

(22) Filed: Nov. 15, 2022

(30) Foreign Application Priority Data
Jan. 28, 2022 (KR) 10-2022-0013003

(51) Int. Cl. H01L 27/11582; H01L 27/11556; H01L 27/11529; H01L 27/11573

(52) U.S. Cl. CPC H01L 27/11582; H01L 27/11556; H01L 27/11529; H01L 27/11573

(57) ABSTRACT

Disclosed are a three-dimensional semiconductor memory device, an electronic system including the same, and a method of fabricating the same. The semiconductor memory device may include a stack structure including electrode layers and electrode interlayer insulating layers, which are alternately stacked on a substrate, vertical semiconductor penetrating the stack structure and placed adjacent to the substrate, and a gate insulating layer between the vertical semiconductor patterns and the stack structure. The gate insulating layer may include a blocking insulating layer adjacent to the stack structure, and charge storing patterns, which are spaced apart from the stack structure with the blocking insulating layer therebetween and are arranged along a surface of the blocking insulating layer. As a distance to the blocking insulating layer decreases, widths of the charge storing patterns may increase.

### CROSS-REFERENCE TO RELATED APPLICATIONS

This U.S. non-provisional patent application claims priority under 35 U.S.C. § 119 to Korean Patent Application No. 10-2022-0013003, filed on Jan. 28, 2022, in the Korean Intellectual Property Office, the entire contents of which are hereby incorporated by reference.

### BACKGROUND

The present disclosure relates to a semiconductor device, an electronic system including the same, and a method of fabricating the same, and in particular, to a highly-integrated and highly-reliable three-dimensional semiconductor memory device, an electronic system including the same, and a method of fabricating the same.

Higher integration of semiconductor devices may be required to satisfy consumer demands for superior performance and inexpensive prices. In the case of semiconductor devices, since their integration may be an important factor in determining product prices, increased integration especially may be required. In the case of two-dimensional or planar semiconductor devices, since integration may be mainly determined by the area occupied by a unit memory cell, integration may be greatly influenced by the level of a fine pattern forming technology. However, extremely expensive process equipment may be needed to increase pattern fineness and may set a practical limitation on increasing integration for two-dimensional or planar semiconductor devices. Thus, three-dimensional semiconductor memory devices including three-dimensionally arranged memory cells have recently been proposed.

### SUMMARY

An embodiment of inventive concepts provides a highly-integrated and highly-reliable three-dimensional semiconductor memory device and an electronic system including the same.

An embodiment of inventive concepts provides a method of fabricating a highly-integrated and highly-reliable three-dimensional semiconductor memory device.

According to an embodiment of inventive concepts, a three-dimensional semiconductor memory device may include a stack structure including electrode layers and electrode interlayer insulating layers alternately stacked on a substrate; vertical semiconductor patterns penetrating the stack structure; and a gate insulating layer between the vertical semiconductor patterns and the stack structure. The gate insulating layer may include a blocking insulating layer and charge storing patterns. The blocking insulating layer may be adjacent to the stack structure. The charge storing patterns may be spaced apart from the stack structure and arranged along a surface of the blocking insulating layer. The blocking insulating layer may be between the charge storing patterns and the stack structure. As a distance to the blocking insulating layer decreases, widths of the charge storing patterns may increase.

According to an embodiment of inventive concepts, a three-dimensional semiconductor memory device may include a peripheral circuit structure; and a cell array structure on the peripheral circuit structure. The cell array structure may include a first substrate, a source structure on the first substrate, a stack structure on the first substrate, a planarization insulating layer, a plurality of vertical semiconductor patterns, bit line pads, and a gate insulating layer between the plurality of vertical semiconductor patterns and the stack structure. The first substrate may include a cell array region and a connection region disposed in a first direction. The stack structure may include electrode layers and electrode interlayer insulating layers alternately stacked on the first substrate. The planarization insulating layer may be on the connection region and may cover an end portion of the stack structure. The plurality of vertical semiconductor patterns may be on the cell array region. The plurality of vertical semiconductor patterns may penetrate the stack structure and the source structure. The plurality of vertical semiconductor patterns may be adjacent to the first substrate. The bit line pads may be on the plurality of vertical semiconductor patterns, respectively. The gate insulating layer may include a blocking insulating layer and charge storing patterns. The blocking insulating layer may be adjacent to the stack structure. The charge storing patterns may be spaced apart from the stack structure and arranged along a surface of the blocking insulating layer. The blocking insulating layer may be between the charge storing patterns and the stack structure. Each of the vertical semiconductor patterns may include silicon crystal grains having a mean size that is larger than a mean size of the charge storing patterns.

According to an embodiment of inventive concepts, an electronic system may include a semiconductor device including a peripheral circuit structure, a cell array structure on the peripheral circuit structure, and an input/output pad electrically connected to the peripheral circuit structure; and a controller electrically connected to the semiconductor device through the input/output pad. The controller may be configured to control the semiconductor device. The cell array structure may include a stack structure on the substrate, vertical semiconductor patterns penetrating the stack structure and placed adjacent to the substrate, and a gate insulating layer between the vertical semiconductor patterns and the stack structure. The stack structure may include electrode layers and electrode interlayer insulating layers alternately stacked on the substrate. The gate insulating layer may include a blocking insulating layer and charge storing patterns. The blocking insulating layer may be adjacent to the stack structure. The charge storing patterns may be spaced apart from the stack structure and arranged along a surface of the blocking insulating layer. The blocking insulating layer may be between the charge storing patterns and the stack structure. As a distance to the blocking insulating layer decreases, widths of the charge storing patterns may increase.

According to an embodiment of inventive concepts, a method of fabricating a three-dimensional semiconductor memory device may include alternately stacking sacrificial layers and electrode interlayer insulating layers on a substrate; etching vertical holes through the electrode interlayer insulating layers and the sacrificial layers to provide a resulting structure with the vertical holes, the vertical holes exposing the substrate; forming a blocking insulating layer on the resulting structure within the vertical holes; forming an amorphous poly-silicon layer on the blocking insulating layer; forming a crystallized silicon layer by performing an annealing process of crystallizing the amorphous poly-silicon layer; etching the crystallized silicon layer to form silicon crystal patterns; and forming a passivation layer on the silicon crystal patterns.

### BRIEF DESCRIPTION OF THE DRAWINGS

FIG. 1A is a diagram schematically illustrating an electronic system including a semiconductor device according to an embodiment of inventive concepts.

FIG. 1B is a perspective view schematically illustrating an electronic system including a semiconductor device according to an embodiment of inventive concepts.

FIGS. 1C and 1D are sectional views, each of which schematically illustrates a semiconductor package according to an embodiment of inventive concepts.

FIG. 2 is a plan view illustrating a three-dimensional semiconductor memory device according to an embodiment of inventive concepts.

FIG. 3 is a sectional view taken along a line A-A′ of FIG. 2.

FIG. 4 is a sectional view taken along a line B-B′ of FIG. 2.

FIG. 5A is an enlarged sectional view illustrating a portion (e.g., ‘P1’ of FIG. 4) of a semiconductor device according to an embodiment of inventive concepts.

FIGS. 5B to 5D are enlarged sectional views, each of which illustrates a portion (e.g., ‘P2’ of FIG. 5A) of a semiconductor device according to an embodiment of inventive concepts.

FIG. 6 is a perspective view illustrating a portion of a three-dimensional semiconductor memory device according to an embodiment of inventive concepts.

FIG. 7A is an enlarged sectional view illustrating a portion (e.g., ‘P1’ of FIG. 4) of a semiconductor device according to an embodiment of inventive concepts.

FIG. 7B is an enlarged sectional view illustrating a portion (e.g., ‘P2’ of FIG. 7A) of a semiconductor device according to an embodiment of inventive concepts.

FIG. 8 is an enlarged sectional view illustrating a portion (e.g., ‘P1’ of FIG. 4) of a semiconductor device according to an embodiment of inventive concepts.

FIG. 9A to 9E are sectional views illustrating a process of fabricating a three-dimensional semiconductor memory device having the section of FIG. 4.

FIG. 10 is a process flow chart illustrating a process of forming charge storing patterns, according to an embodiment of inventive concepts.

FIG. 11A to 11E are sectional views illustrating a portion (e.g., ‘P1’ of FIG. 9C) during the fabrication process.

FIG. 12 is a sectional view illustrating a semiconductor device according to an embodiment of inventive concepts.

### DETAILED DESCRIPTION

Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”) may be construed as A only, B only, C only, or any combination of two or more of A, B, and C, such as, for instance, ABC, AB, BC, and AC.

Example embodiments of inventive concepts will now be described more fully with reference to the accompanying drawings, in which example embodiments are shown.

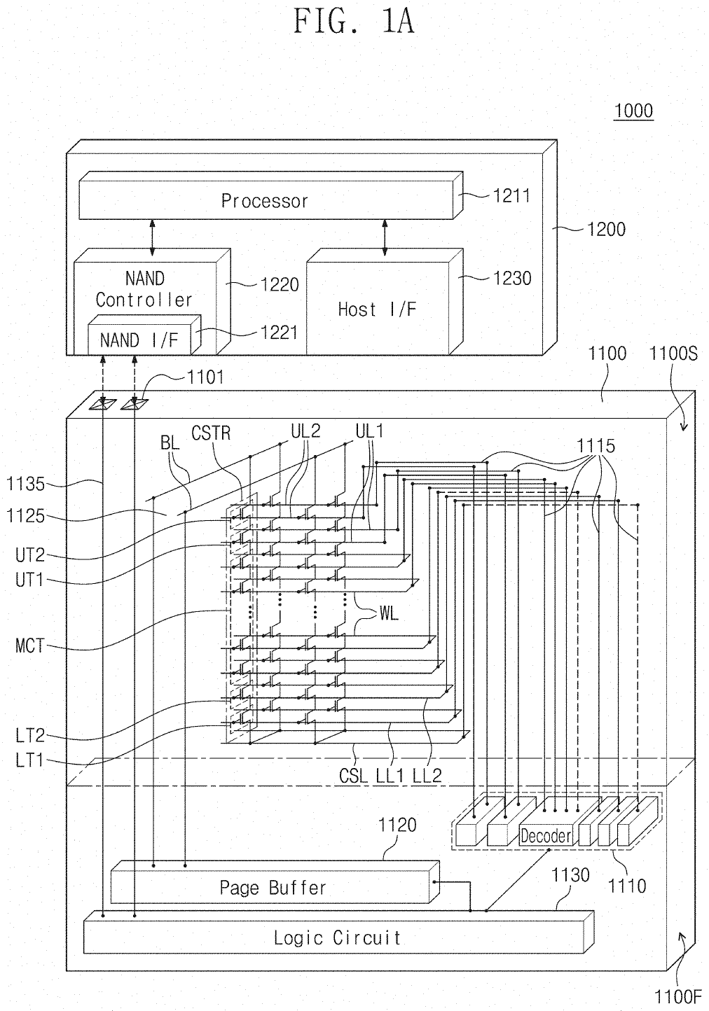

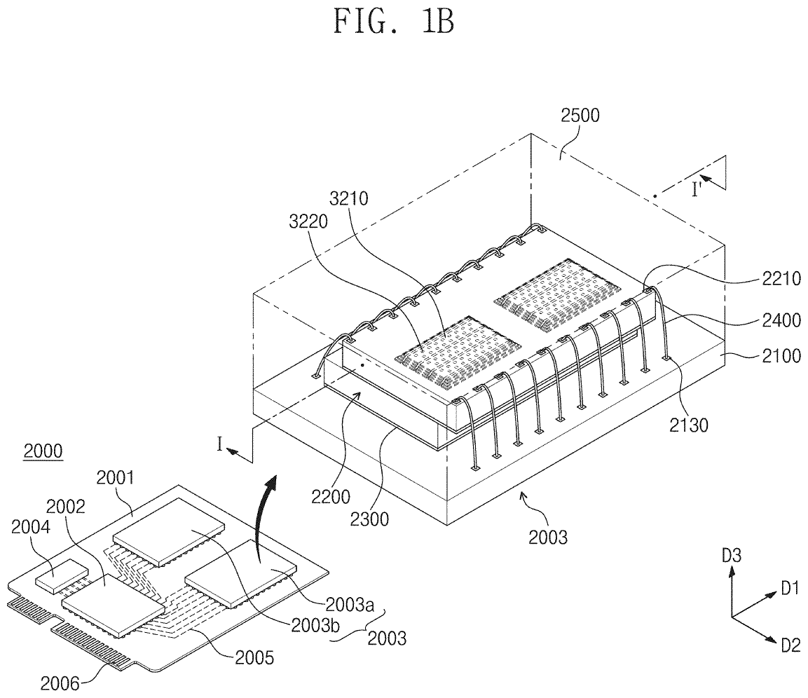

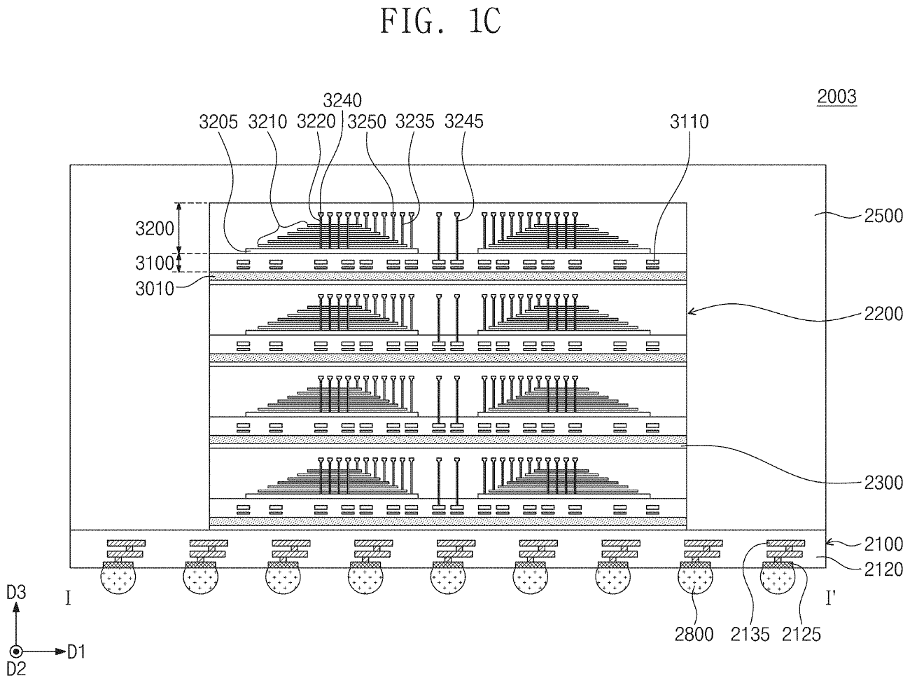

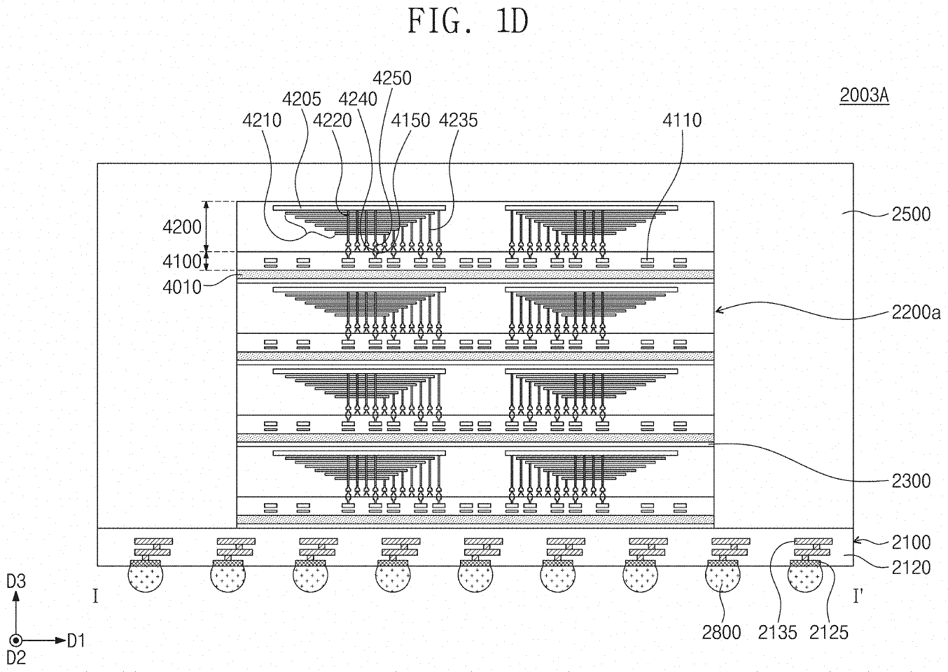

FIG. 1A is a diagram schematically illustrating an electronic system including a semiconductor device according to an embodiment of inventive concepts.

Referring to FIG. 1A, an electronic system 1000 according to an embodiment of inventive concepts may include a semiconductor device 1100 and a controller 1200 electrically connected to the semiconductor device 1100. The electronic system 1000 may be a storage device including one or more semiconductor devices 1100 or an electronic device including the storage device. For example, the electronic system 1000 may be a solid state drive (SSD) device, a universal serial bus (USB), a computing system, a medical system, or a communication system, in which at least one semiconductor device 1100 is provided.

The semiconductor device 1100 may be a nonvolatile memory device (e.g., a NAND FLASH memory device). The semiconductor device 1100 may include a first structure 1100F and a second structure 1100S on the first structure 1100F. In an embodiment, the first structure 1100F may be disposed beside the second structure 1100S. The first structure 1100F may be a peripheral circuit structure including a decoder circuit 1110, a page buffer circuit 1120, and a logic circuit 1130. The second structure 1100S may be a memory cell structure including a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of the lower transistors LT1 and LT2 and the number of the upper transistors UT1 and UT2 may be variously changed, according to embodiments.

In an embodiment, the upper transistors UT1 and UT2 may include at least one string selection transistor, and the lower transistors LT1 and LT2 may include at least one ground selection transistor. The gate lower lines LL1 and LL2 may be respectively used as gate electrodes of the lower transistors LT1 and LT2. The word lines WL may be respectively used as gate electrodes of the memory cell transistors MCT, and the gate upper lines UL1 and UL2 may be respectively used as gate electrodes of the upper transistors UT1 and UT2.

In an embodiment, the lower transistors LT1 and LT2 may include a lower erase control transistor LT1 and a ground selection transistor LT2, which are connected in series. The upper transistors UT1 and UT2 may include a string selection transistor UT1 and an upper erase control transistor UT2, which are connected in series. At least one of the lower and upper erase control transistors LT1 and UT2 may be used for an erase operation of erasing data, which are stored in the memory cell transistors MCT, using a gate-induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection lines 1115, which are extended from the first structure 1100F into the second structure 1100S. The bit lines BL may be electrically connected to the page buffer circuit 1120 through second connection lines 1125, which are extended from the first structure 1100F to the second structure 1100S.

In the first structure 1100F, the decoder circuit 1110 and the page buffer circuit 1120 may be configured to perform a control operation on at least one memory cell transistor MCT selected from the memory cell transistors MCT. The decoder circuit 1110 and the page buffer circuit 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The controller 1200 may include a processor 1211, a NAND controller 1220, and a host interface 1230. In an embodiment, the electronic system 1000 may include a plurality of semiconductor devices 1100, and in this case, the controller 1200 may control the semiconductor devices 1100.

The processor 1211 may control overall operations of the electronic system 1000 including the controller 1200. The processor 1211 may be operated based on a specific firmware and may control the NAND controller 1220 to access the semiconductor device 1100. The NAND controller 1220 may include a NAND interface 1221 which is used for communication with the semiconductor device 1100. The NAND interface 1221 may be used to transmit and receive control commands, which are used to control the semiconductor device 1100, and data, which will be written in or read from the memory cell transistors MCT of the semiconductor device 1100. The host interface 1230 may be configured to allow for communication between the electronic system 1000 and an external host. When a control command is received from the external host through the host interface 1230, the processor 1211 may control the semiconductor device 1100 in response to the control command.

FIG. 1B is a perspective view schematically illustrating an electronic system including a semiconductor device according to an embodiment of inventive concepts.

Referring to FIG. 1B, an electronic system 2000 according to an embodiment of inventive concepts may include a main substrate 2001 and a controller 2002, at least one semiconductor package 2003, and a DRAM 2004, which are mounted on the main substrate 2001. The semiconductor package 2003 and the DRAM 2004 may be connected to the controller 2002 by interconnection patterns 2005, which are formed in the main substrate 2001.

The main substrate 2001 may include a connector 2006, which includes a plurality of pins coupled to an external host. In the connector 2006, the number and arrangement of the pins may be changed depending on a communication interface between the electronic system 2000 and the external host. In an embodiment, the electronic system 2000 may communicate with the external host, in accordance with one of interfaces, such as universal serial bus (USB), peripheral component interconnect express (PCI-Express), serial advanced technology attachment (SATA), universal flash storage (UFS) M-Phy, or the like. In an embodiment, the electronic system 2000 may be driven by a power, which is supplied from the external host through the connector 2006. The electronic system 2000 may further include a power management integrated circuit (PMIC) that is configured to distribute a power, which is supplied from the external host, to the controller 2002 and the semiconductor package 2003.

The controller 2002 may be configured to control a writing or reading operation on the semiconductor package 2003 and to improve an operation speed of the electronic system 2000.

The DRAM 2004 may be a buffer memory, which relieves technical difficulties caused by a difference in speed between the semiconductor package 2003, which serves as a data storage device, and an external host. In an embodiment, the DRAM 2004 in the electronic system 2000 may serve as a cache memory and may be used as a storage space, which is configured to store data temporarily during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 disposed on respective bottom surfaces of the semiconductor chips 2200, a connection structure 2400 electrically connecting the semiconductor chips 2200 to the package substrate 2100, and a molding layer 2500 disposed on the package substrate 2100 to cover the semiconductor chips 2200 and the connection structure 2400.

The package substrate 2100 may be a printed circuit board including package upper pads 2130. Each of the semiconductor chips 2200 may include an input/output pad 2210. The input/output pad 2210 may correspond to the input/output pad 1101 of FIG. 1A. Each of the semiconductor chips 2200 may include gate stacks 3210 and vertical structures 3220. Each of the semiconductor chips 2200 may include a semiconductor device, which will be described below, according to an embodiment of inventive concepts.

In an embodiment, the connection structure 2400 may be a bonding wire, which is provided to electrically connect the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively, in each of the first and second semiconductor packages 2003a and 2003b, the semiconductor chips 2200 may be electrically connected to each other by a connection structure including through-silicon vias (TSVs), not by the connection structure 2400 provided in the form of bonding wires.

In an embodiment, the controller 2002 and the semiconductor chips 2200 may be included in a single package. In an embodiment, the controller 2002 and the semiconductor chips 2200 may be mounted on an additional interposer substrate different from the main substrate 2001 and may be connected to each other through interconnection lines, which are provided in the interposer substrate.

FIGS. 1C and 1D are sectional views, each of which schematically illustrates a semiconductor package according to an embodiment of inventive concepts. FIGS. 1C and 1D are sectional views taken along a line I-I′ of FIG. 1B and illustrate two different examples of the semiconductor package of FIG. 1B.

Referring to FIG. 1C, the package substrate 2100 of the semiconductor package 2003 may be a printed circuit board. The package substrate 2100 may include a package substrate body portion 2120, the package upper pads 2130 (e.g., see FIG. 1B), which are disposed on a top surface of the package substrate body portion 2120, lower pads 2125, which are disposed on or exposed through a bottom surface of the package substrate body portion 2120, and internal lines 2135, which are disposed in the package substrate body portion 2120 to electrically connect the package upper pads 2130 to the lower pads 2125. The package upper pads 2130 may be electrically connected to the connection structures 2400. The lower pads 2125 may be connected to the interconnection patterns 2005 of the main substrate 2001 of the electronic system 2000 shown in FIG. 1B through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region including peripheral lines 3110. The second structure 3200 may include a source structure 3205, a stack 3210 on the source structure 3205, the vertical structures 3220 penetrating the stack 3210, bit lines 3240 electrically connected to the vertical structures 3220, and cell contact plugs 3235 electrically connected to the word lines WL (e.g., see FIG. 1) of the stack 3210. Each of the first and second structures 3100 and 3200 and the semiconductor chips 2200 may further include separation structures to be described below.

Each of the semiconductor chips 2200 may include a penetration line 3245, which is electrically connected to the peripheral lines 3110 of the first structure 3100 and is extended into the second structure 3200. The penetration line 3245 may be disposed outside the stack 3210, and in an embodiment, the penetration line 3245 may be provided to further penetrate the stack 3210. Each of the semiconductor chips 2200 may further include the input/output pad 2210 (e.g., see FIG. 1B), which is electrically connected to the peripheral lines 3110 of the first structure 3100.

Referring to FIG. 1D, in the semiconductor package 2003A, each of the semiconductor chips 2200a may include a semiconductor substrate 4010, a first structure 4100 on the semiconductor substrate 4010, and a second structure 4200, which is provided on the first structure 4100 and is bonded to the first structure 4100 in a wafer bonding manner.

The first structure 4100 may include a peripheral circuit region including a peripheral line 4110 and first junction structures 4150. The second structure 4200 may include a source structure 4205, a stack 4210 between the source structure 4205 and the first structure 4100, vertical structures 4220 penetrating the stack 4210, and second junction structures 4250, which are electrically and respectively connected to the vertical structures 4220 and the word lines WL (e.g., see FIG. 1A) of the stack 4210. For example, the second junction structures 4250 may be electrically connected to the vertical structures 4220 and the word lines WL (e.g., see FIG. 1A), respectively, through bit lines 4240 electrically connected to the vertical structures 4220 and cell contact plugs 4235 electrically connected to the word lines WL (e.g., see FIG. 1A). The first junction structures 4150 of the first structure 4100 may be in contact with and bonded to the second junction structures 4250 of the second structure 4200. The bonded portions of the first junction structures 4150 and the second junction structures 4250 may be formed of or include, for example, copper Cu.

Each of the first and second structures 4100 and 4200 and the semiconductor chips 2200a may further include a source structure according to an embodiment to be described below. Each of the semiconductor chips 2200a may further include the input/output pad 2210 (e.g., see FIG. 1B), which is electrically connected to the peripheral lines 4110 of the first structure 4100.

The semiconductor chips 2200 of FIG. 1C and the semiconductor chips 2200a of FIG. 1D may be electrically connected to each other by the connection structures 2400, which are provided in the form of bonding wires. However, in an embodiment, semiconductor chips provided in each semiconductor package (e.g., the semiconductor chips 2200 of FIG. 1C and the semiconductor chips 2200a of FIG. 1D) may be electrically connected to each other through a connection structure including through-silicon vias (TSVs).

The first structure 3100 of FIG. 1C and the first structure 4100 of FIG. 1D may correspond to a peripheral circuit structure in an embodiment to be described below, and the second structure 3200 of FIG. 1C and the second structure 4200 of FIG. 1D may correspond to a cell array structure in an embodiment to be described below.

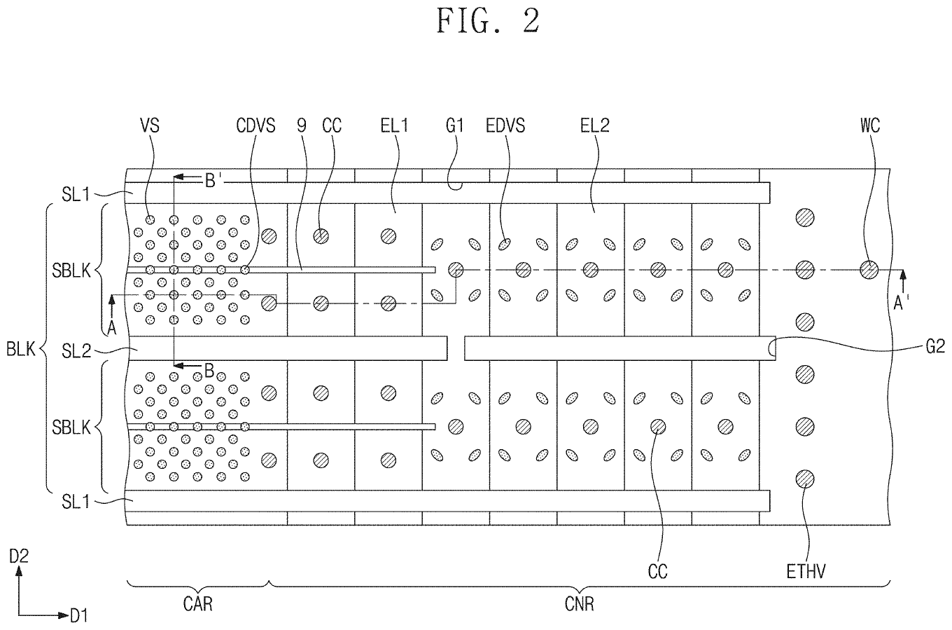

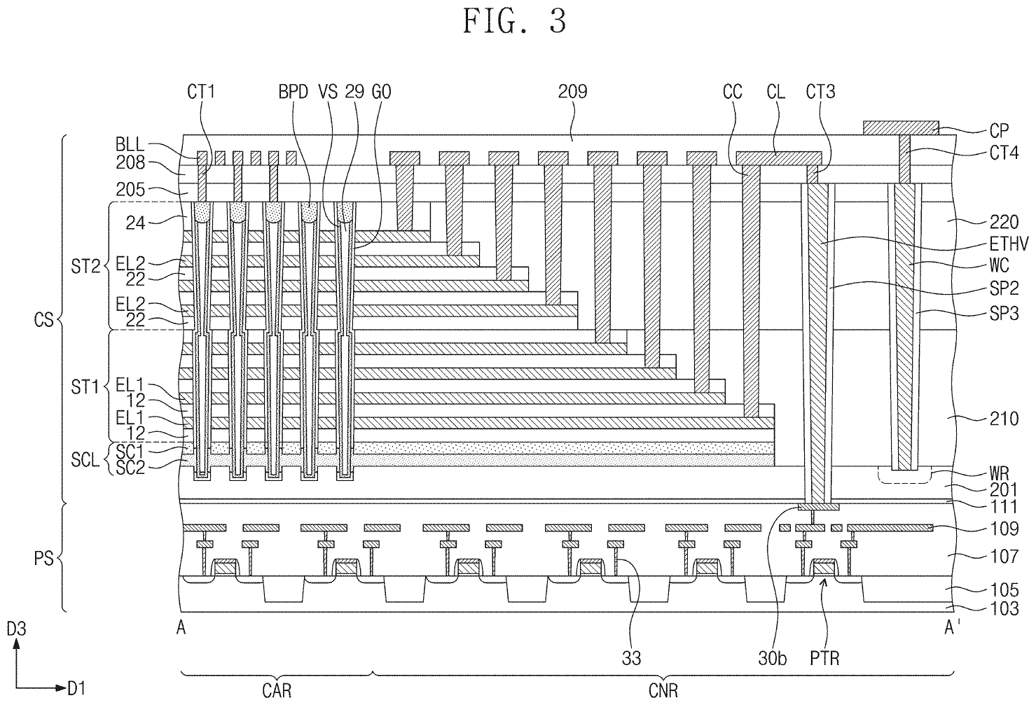

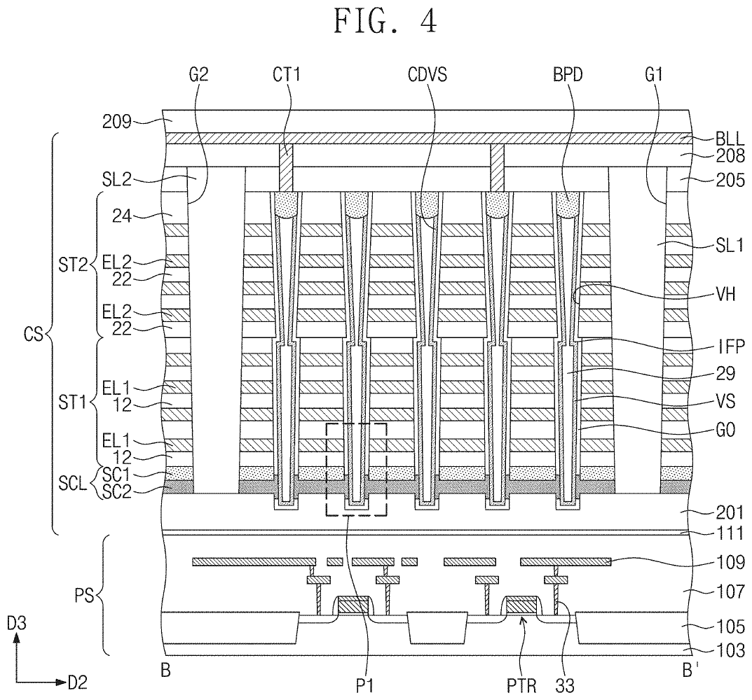

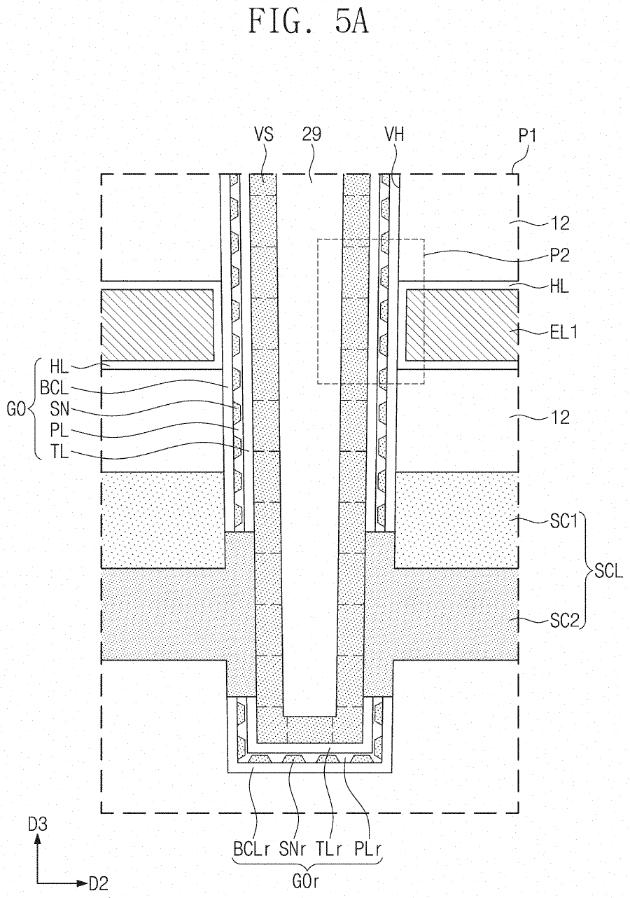

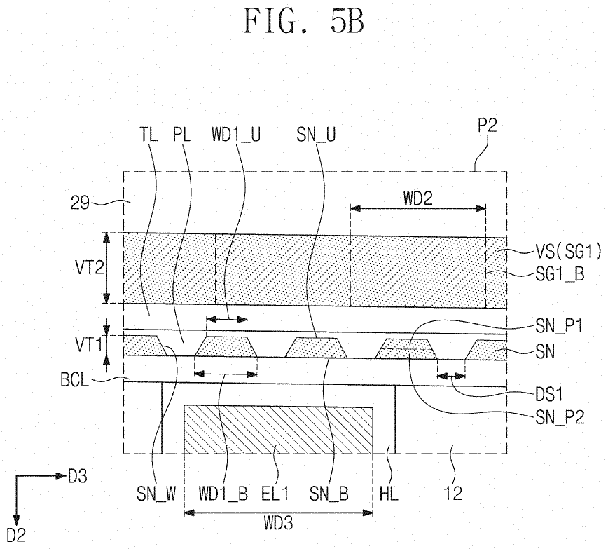

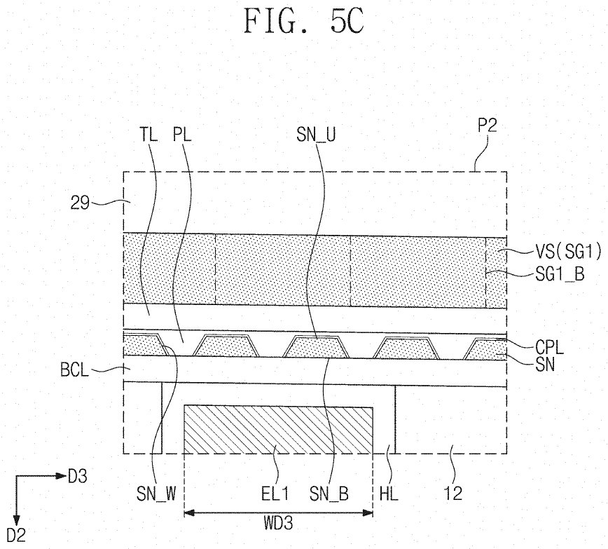

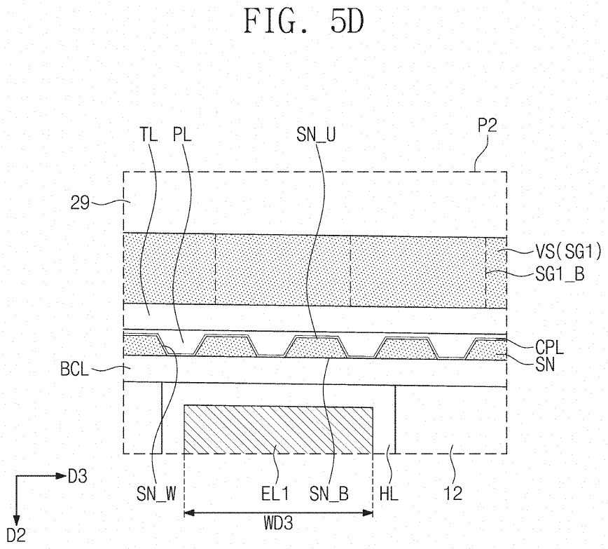

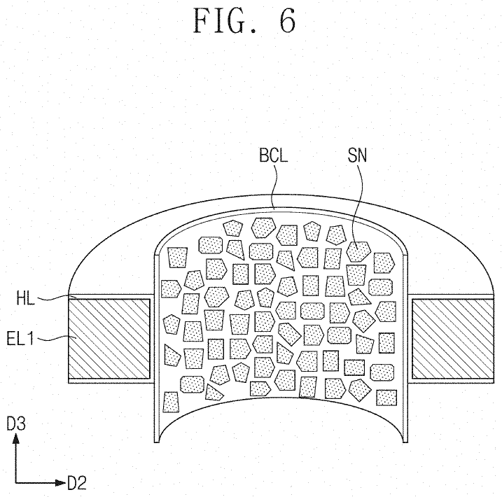

FIG. 2 is a plan view illustrating a three-dimensional semiconductor memory device according to an embodiment of inventive concepts. FIG. 3 is a sectional view taken along a line A-A′ of FIG. 2. FIG. 4 is a sectional view taken along a line B-B′ of FIG. 2. FIG. 5A is an enlarged sectional view illustrating a portion (e.g., ‘P1’ of FIG. 4) of a semiconductor device according to an embodiment of inventive concepts. FIGS. 5B to 5D are enlarged sectional views, each of which illustrates a portion (e.g., ‘P2’ of FIG. 5A) of a semiconductor device according to an embodiment of inventive concepts. FIG. 6 is a perspective view illustrating a portion of a three-dimensional semiconductor memory device according to an embodiment of inventive concepts.

Referring to FIGS. 2, 3, and 4, a cell array structure CS may be disposed on a peripheral circuit structure PS. The cell array structure CS may include blocks BLK, which are arranged in a second direction D2. Most of the blocks BLK may be a memory block, on which data programming, reading, and erasing operations are performed. Alternatively, some of the blocks BLK may be a dummy block, on which data programming, reading, and erasing operations are not performed. The blocks BLK may be separated from each other by first insulating isolation lines SL1. FIG. 2 illustrates one of the blocks BLK.

The first insulating isolation line SL1 may extend in a first direction D1 crossing the second direction D2. The first insulating isolation line SL1 may be disposed in a first groove G1. The first insulating isolation line SL1 may include at least one of a silicon oxide layer, a silicon nitride layer, a silicon oxynitride layer, and a porous insulating layer and may have a single or multi-layered structure. Each of the blocks BLK may include a cell array region CAR and connection regions CNR disposed at both side of the cell array region CAR.

Each block BLK may be divided into two sub-blocks SBLK by a second insulating isolation line SL2, which is extended in the first direction D1 and passes through a center thereof. The second insulating isolation line SL2 may not be cut in the cell array region CAR and may be extended to the connection region CNR. The second insulating isolation line SL2 may be cut in the connection region CNR and may be divided into two portions. The second insulating isolation line SL2 may be disposed in a second groove G2.

The peripheral circuit structure PS may include a first substrate 103. The first substrate 103 may be a single crystalline silicon substrate or a silicon-on-insulator (SOI) substrate. A device isolation layer 105 may be disposed in the first substrate 103 to delimit active regions. Peripheral transistors PTR may be disposed on the active regions. Each of the peripheral transistors PTR may include a peripheral gate electrode, a peripheral gate insulating layer, and peripheral source/drain regions, which are formed in the first substrate 103 and at both sides of the peripheral gate electrode. The peripheral transistors PTR may be covered with a peripheral interlayer insulating layer 107. The peripheral interlayer insulating layer 107 may include at least one of a silicon oxide layer, a silicon nitride layer, a silicon oxynitride layer, and a porous insulating layer and may have a single or multi-layered structure. Peripheral lines 109 and peripheral contacts 33 may be disposed in the peripheral interlayer insulating layer 107. The peripheral lines 109 and the peripheral contacts 33 may be formed of or include at least one of conductive materials.

Some of the peripheral lines 109 and the peripheral contacts 33 may be electrically connected to the peripheral transistors PTR. The peripheral lines 109 and the peripheral transistors PTR may constitute the page buffer circuit 1120 and the decoder circuit 1110 of FIG. 1A. The peripheral circuit structure PS may include conductive pads 30b provided at the topmost level thereof.

An etch stop layer 111 may be disposed on the peripheral circuit structure PS. The etch stop layer 111 may be formed of or include a material having an etch selectivity with respect to a second substrate 201 and the peripheral interlayer insulating layer 107. For example, the etch stop layer 111 may be formed of or include silicon nitride or silicon oxide. The etch stop layer 111 may be referred to as an ‘adhesive layer’.

Each block BLK in the cell array structure CS may include the second substrate 201, a source structure SCL, a first sub-stack structure ST1, a second sub-stack structure ST2, and first to third upper insulating layers 205, 208, and 209, which are sequentially stacked. The first sub-stack structure ST1 may include first electrode layers EL1 and first electrode interlayer insulating layers 12, which are alternately stacked. The second sub-stack structure ST2 may include second electrode layers EL2 and second electrode interlayer insulating layers 22, which are alternately stacked, and an uppermost second electrode interlayer insulating layer 24, which is provided at the uppermost level of the second sub-stack structure ST2. The second substrate 201 may be, for example, a single crystalline silicon layer, a silicon epitaxial layer, or a SOI substrate. The second substrate 201 may be doped with impurities of a first conductivity type. In an embodiment, the impurity may be boron, and the first conductivity type may be p-type. In an embodiment, the impurity may be arsenic or phosphorus and the first conductivity type may be n-type.

The lowermost and next lowermost ones of the first electrode layers EL1 may correspond to the first and second gate lower lines LL1 and LL2 of FIG. 1A or may correspond to the gate electrodes of the lower transistors LT1 and LT2 (e.g., the lower erase control transistor LT1 and the ground selection transistor LT2).

In each sub-block SBLK, at least two topmost ones of the second electrode layers EL2 may be divided into a plurality of lines, which are used as the gate upper lines UL1 and UL2, by a source groove CG. The lowermost and next lowermost ones of the second electrode layers EL2 may correspond to the gate electrodes of the upper transistors UT1 and UT2 (e.g., the upper erase control transistor UT2 and the string selection transistor UT1), respectively. The remaining ones of the electrode layers EL1 and EL2 may serve as the word lines WL of FIG. 1A. In an embodiment, at least one of the remaining ones of the electrode layers EL1 and EL2 may correspond to a dummy word line, which is not used for an actual operation.

The electrode layers EL1 and EL2 may be formed of or include at least one of, for example, doped semiconductor materials (e.g., doped silicon), metallic materials (e.g., tungsten, copper, or aluminum), conductive metal nitrides (e.g., titanium nitride or tantalum nitride), or transition metals (e.g., titanium or tantalum). The electrode interlayer insulating layers 12, 22, and 24 may have a single- or multi-layered structure including at least one of a silicon oxide layer, a silicon nitride layer, a silicon oxynitride layer, or a porous insulating layer.

The source structure SCL may include a first source pattern SC1, which is interposed between the lowermost electrode interlayer insulating layer 12 and the second substrate 201, and a second source pattern SC2, which is interposed between the first source pattern SC1 and the second substrate 201. The first source pattern SC1 may include a doped semiconductor pattern (e.g., a doped polysilicon pattern of the first conductivity type). The second source pattern SC2 may include a doped semiconductor pattern (e.g., a doped polysilicon pattern). The second source pattern SC2 may further include a semiconductor material that is different from the first source pattern SC1. The second source pattern SC2 may have the same conductivity type as the first source pattern SC1. A doping concentration of the second source pattern SC2 may be equal to or different from that of the first source pattern SC1. The source structure SCL may correspond to the common source line CSL of FIG. 1A. In addition, the second substrate 201 may serve as the common source line CSL of FIG. 1A.

Referring to FIGS. 2 and 4, in the cell array region CAR of each of the sub-blocks SBLK, cell vertical patterns (or vertical semiconductor patterns) VS and center dummy vertical patterns CDVS may be provided to penetrate the electrode interlayer insulating layers 12, 22, and 24 and the electrode layers EL1 and EL2. The central dummy vertical patterns CDVS may be arranged to form a single column parallel to the first direction D1. A central separation pattern 9 may be disposed between upper portions of the central dummy vertical patterns CDVS. A gate insulating layer GO may be interposed between the electrode layers EL1 and EL2 and the cell vertical patterns VS and between the electrode layers EL1 and EL2 and the central dummy vertical patterns CDVS.

In an embodiment, each of the cell vertical patterns VS and the central dummy vertical patterns CDVS may have a hollow cup shape. A sidewall of each of the cell vertical patterns VS and the central dummy vertical patterns CDVS may have an inflection point IFP, which is located near an interface between the first and second sub-stack structures ST1 and ST2, as shown in FIG. 4C.

An internal space of each of the cell vertical patterns VS and the central dummy vertical patterns CDVS may be filled with an insulating gapfill pattern 29. The insulating gapfill pattern 29 may have a single- or multi-layered structure including at least one of, for example, a silicon oxide layer, a silicon nitride layer, or a silicon oxynitride layer. A bit line pad BPD may be disposed on each of the cell vertical patterns VS and the central dummy vertical patterns CDVS. The bit line pad BPD may be formed of or include at least one of doped polysilicon or metallic materials (e.g., tungsten, aluminum, and copper).

Referring to FIGS. 5A to 6, the gate insulating layer GO may include a tunnel insulating layer TL, a passivation layer PL, charge storing patterns SN, and a blocking insulating layer BCL. The tunnel insulating layer TL may be formed of at least one of insulating layers, whose band gaps are greater than that of the charge storing patterns SN. For example, the tunnel insulating layer TL may be formed of or include silicon oxide. The blocking insulating layer BCL may be formed of or include at least one of silicon oxide or high-k dielectric materials having dielectric constants higher than silicon oxide. For example, the high-k dielectric materials may be formed of or include at least one of metal oxide materials (e.g., aluminum oxide and hafnium oxide).

Each of the charge storing patterns SN may be or include a doped or undoped silicon crystal pattern. The silicon crystal pattern may be referred to as a ‘nanocrystalline silicon (nanocrystalline Si)’ or ‘silicon nanocrystal’. The silicon crystal pattern may be doped with phosphorus, arsenic, or boron. The charge storing patterns SN may be in contact with the blocking insulating layer BCL and may be spaced apart from the cell vertical patterns VS and the center dummy vertical patterns CDVS. The charge storing patterns SN may be spaced apart from each other.

As shown in FIGS. 5A to 5D, a side surface SN_W of the charge storing patterns SN may be inclined to a surface of the blocking insulating layer BCL. Each of the charge storing patterns SN may have a trapezoidal section. Each of the charge storing patterns SN may include a first portion SN_P1 and a second portion SN_P2. In each charge storing pattern SN, the first and second portions SN_P1 and SN_P2 may be connected to form a single object. The second portions SN_P2 may be in contact with the blocking insulating layer, and the first portions SN_P1 may be spaced apart from the blocking insulating layer. A width of the first portions SN_P1 may be different from a width of the second portions SN_P2. In an embodiment, the width of the first portions SN_P1 may be smaller than the width of the second portions SN_P2. As a distance to the blocking insulating layer BCL decreases, a first width WD1 of each of the charge storing patterns SN may increase. A width WD1_U of a top surface SN_U of each of the charge storing patterns SN may be smaller than a width WD1_B of a bottom surface SN_B of each of the charge storing patterns SN.

In an embodiment, the width WD1_U of the top surface SN_U of each of the charge storing patterns SN may be larger than the width WD1_B of the bottom surface SN_B of each of the charge storing patterns SN. As a distance to the blocking insulating layer BCL decreases, the first width WD1 of each of the charge storing patterns SN may decrease.

In an embodiment, the charge storing patterns SN may be provided to have the same shape, size, thickness, and distance. Alternatively, the charge storing patterns SN may be provided to have similar or uniform shapes, sizes, thicknesses, and distances.

A mean value of the width WD1_U of the top surface SN_U of each of the charge storing patterns SN may range from 3 nm to 10 nm. In the present specification, a ‘width’ of an element may mean a ‘(mean) size’ or ‘(mean) diameter’ of the element. A distance DS1 between the charge storing patterns SN may range from 1 Å to 10 nm.

As shown in FIG. 6, the charge storing patterns SN may be two-dimensionally disposed along a surface of the blocking insulating layer BCL. When viewed in a direction normal to the surface of the blocking insulating layer BCL, each of the charge storing patterns SN may have a polygonal shape (e.g., rectangular, tetragonal, trapezoidal, pentagonal, hexagonal, heptagonal, and octagonal shapes). In the three-dimensional semiconductor memory device, a variation coefficient (or dispersion/fluctuation rate) of the widths WD1_U of the top surfaces SN_U of the charge storing patterns SN may be 0.5-10% of the widths WD1_U. A variation coefficient (or dispersion/fluctuation rate) of the distance DS1 between the charge storing patterns SN may be 0.5-10% of the distance DS1.

In the present embodiment, the charge storing patterns SN may be spaced apart from each other. In this case, it may be possible to reduce lateral/vertical charge loss, compared to the case that the charge storing patterns SN are connected to each other. That is, it may be possible to limit and/or prevent a charge spreading phenomenon and thereby to improve the reliability of the three-dimensional semiconductor memory device.

Furthermore, the widths WD1_U and distances of the charge storing patterns SN may have uniform values whose variation coefficient (or dispersion/fluctuation rate) is less than 10%. Thus, it may be possible to improve uniformity and reliability characteristics in data writing/erasing operations on the charge storing patterns SN. This may allow for the Fowler-Nordheim erase operation, and thus, it may be possible to increase an operation speed in the program/erase operation and to perform the erase operation in a deep erase manner. As a result, the erase saturation characteristics may be improved.

As shown in FIGS. 5A to 5D, the charge storing patterns SN may be covered with the passivation layer PL. The passivation layer PL may be formed of or include at least one of SiN, SiO, SiON, or metal oxide materials and may have a single- or multi-layered structure.

As shown in FIG. 5B, the passivation layer PL may be in direct contact with surfaces of the charge storing patterns SN. Here, the passivation layer PL may limit and/or prevent defects, such as dangling bonds, from being formed on the surfaces of the charge storing patterns SN and this may make it possible to reduce the lateral/vertical charge loss. The passivation layer PL may be placed between the charge storing patterns SN and may be in contact with the blocking insulating layer BCL.

Alternatively, as shown in FIG. 5C, the top and side surfaces SN_U and SN_W of the charge storing patterns SN may be covered with a capping layer CPL. The passivation layer PL may be placed between the charge storing patterns SN and may be in contact with the blocking insulating layer BCL. Alternatively, as shown in FIG. 5D, the top and side surfaces SN_U and SN_W of the charge storing patterns SN and the blocking insulating layer BCL may be covered with the capping layer CPL. The passivation layer PL may be placed between the charge storing patterns SN and may be spaced apart from the blocking insulating layer BCL. The capping layer CPL may be formed of or include silicon oxide or silicon nitride. The capping layer CPL may limit and/or prevent defects, such as dangling bonds, from being formed on surfaces of the charge storing patterns SN, and in this case, it may be possible to reduce the lateral/vertical charge loss.

The cell vertical patterns VS and the center dummy vertical patterns CDVS may be formed of or include at least one of, for example undoped single-crystalline silicon or polysilicon. Alternatively, each of the cell vertical patterns VS and the center dummy vertical patterns CDVS may have first silicon crystal grains SG1. A first boundary SG1_B or first crystal grain boundaries may exist between the first silicon crystal grains SG1. Each of the first silicon crystal grains SG1 may have a second width WD2 (or a second mean size), when measured in a direction (e.g., a third direction D3) parallel to the surface of the blocking insulating layer BCL. The second width WD2 may be different from the first width WD1 (or a first mean size) of each of the charge storing patterns SN. In an embodiment, the second width WD2 may be larger than the first width WD1 (or the first mean size) of each of the charge storing patterns SN. In another embodiment, the second width WD2 may be smaller than the first width WD1 (or the first mean size) of each of the charge storing patterns SN.

Each of the charge storing patterns SN may have a first vertical thickness VT1 in a direction (e.g., the second direction D2) normal to the surface of the blocking insulating layer BCL. Each of the cell vertical patterns VS and the center dummy vertical patterns CDVS may have a second vertical thickness VT2 in the direction (e.g., the second direction D2) normal to the surface of the blocking insulating layer BCL. The first vertical thickness VT1 may be smaller than the second vertical thickness VT2.

Each of the electrode layers EL1 and EL2 may have a third width WD3 in the third direction D3. The third width WD3 of each of the electrode layers EL1 and EL2 may be smaller than the width WD1_U of the top surface SN_U of the charge storing patterns SN.

The gate insulating layer GO may further include a high-k dielectric layer HL. The high-k dielectric layer HL may be interposed between the blocking insulating layer BCL and the electrode layers EL1 and EL2. The high-k dielectric layer HL may be interposed between the electrode layers EL1 and EL2 and the electrode interlayer insulating layers 12, 22, and 24. The high-k dielectric layer HL may have a dielectric constant higher than the silicon oxide layer and may include a metal oxide layer (e.g., a hafnium oxide layer and an aluminum oxide layer).

The second source pattern SC2 may be provided to penetrate the gate insulating layer GO and to be in contact with the cell vertical patterns VS. A lower portion of the gate insulating layer GO may be separated from an upper portion of the gate insulating layer GO by the second source pattern SC2. Accordingly, the lower portion of the gate insulating layer GO may be spaced apart from an upper portion of the gate insulating layer GO by the second source pattern SC2 and may form a residual gate insulating layer GOr.

The remaining gate insulating layer GOr may include a remaining tunnel insulating layer TLr, a remaining passivation layer PLr, remaining charge storing patterns SNr, and a remaining blocking insulating layer BCLr. The remaining tunnel insulating layer TLr may be a portion of the tunnel insulating layer TL. The remaining passivation layer PLr may be a portion of the passivation layer PL. The remaining charge storing patterns SNr may be provided to have the same shape, structure, and material as the charge storing pattern SN. The remaining charge storing patterns SNr may be dummy charge storing patterns, which are not used to store data. The remaining blocking insulating layer BCLr may be a portion of the blocking insulating layer BCL.

Referring back to FIG. 4, each of the first and second insulating isolation lines SL1 and SL2 may be provided to penetrate the first upper insulating layer 205 and the sub-stack structures ST1 and ST2. In an embodiment, each of the first and second insulating isolation lines SL1 and SL2 may be formed of or include silicon oxide. In the present embodiment, the first and second insulating isolation lines SL1 and SL2 may penetrate the source structure SCL and may be in contact with the second substrate 201. In another embodiment, the first and second insulating isolation lines SL1 and SL2 may penetrate the first source pattern SC1 of the source structure SCL and may be in contact with the second source pattern SC2. Bottom surfaces of the first and second insulating isolation lines SL1 and SL2 may be located at the same level.

Although not shown, a source conductive plug or a source conductive line may be disposed in at least one of the first and second insulating isolation lines SL1 and SL2 to be in contact with the second substrate 201 or the source structure SCL.

Referring to FIGS. 3 and 4, the second upper insulating layer 208 may be disposed on the first upper insulating layer 205. First conductive lines BLL may be disposed on the second upper insulating layer 208 to extend in the second direction D2 or parallel to each other. The first conductive lines BLL may correspond to the bit lines BL of FIG. 1A. First contacts CT1 may be disposed on the cell array region CAR to penetrate the first and second upper insulating layers 205 and 208 and to connect the bit line pads BPD, which are disposed on the cell vertical patterns VS, to one of the first conductive lines BLL.

Referring to FIGS. 2 and 3, the sub-stack structures ST1 and ST2 in each of the blocks BLK may have a stepwise shape on the connection region CNR. For example, the electrode layers EL1 and EL2 and the electrode interlayer insulating layers 12, 22, and 24 may be provided to have the stepwise shape on the connection region CNR. As a distance to the peripheral circuit structure PS decreases, the electrode layers EL1 and EL2 and the electrode interlayer insulating layers 12, 22, and 24 may have increasing lengths and protrude shapes in the first direction D1. An end portion of the first sub-stack structure ST1 on the connection region CNR may be covered with a first planarization insulating layer 210. An end portion of the second sub-stack structure ST2 on the connection region CNR may be covered with a second planarization insulating layer 220. Each of the first and second planarization insulating layers 210 and 220 may include a silicon oxide layer or a porous insulating layer. The first to third upper insulating layers 205, 208, and 209 may be sequentially formed on the first and second planarization insulating layers 210 and 220.

End portions of the electrode layers EL1 and EL2 may be connected to cell contact plugs CC, respectively. The cell contact plugs CC may be provided to penetrate the first and second upper insulating layers 205 and 208 and the electrode interlayer insulating layers 12, 22, and 24 and to be in contact with the electrode layers EL1 and EL2, respectively.

Referring to FIG. 2, edge dummy vertical patterns EDVS may be provided to penetrate the planarization insulating layers 210 and 220 as well as the end portions of the electrode layers EL1 and EL2 and the electrode interlayer insulating layers 12, 22, and 24 constituting the stepwise shape. The edge dummy vertical patterns EDVS may have an elliptical shape that is elongated in a specific direction when viewed in a plan view. The edge dummy vertical patterns EDVS may have the same or similar section as the cell vertical pattern VS of FIG. 4. Inner spaces of the edge dummy vertical patterns EDVS may also be filled with the insulating gapfill pattern 29. The gate insulating layer GO may be interposed between the edge dummy vertical patterns EDVS and the electrode layers EL1 and EL2. In an embodiment, the bit line pad BPD may be disposed on the edge dummy vertical patterns EDVS. However, the edge dummy vertical patterns EDVS may not be connected to the first conductive line BLL.

Referring back to FIG. 3, an electrode connection line CL may be disposed on the second upper insulating layer 208. In the connection region CNR, an edge through via ETHV may be provided to penetrate the first upper insulating layer 205, the planarization insulating layers 210 and 220, the second substrate 201, and the etch stop layer 111 and may be in contact with the peripheral conductive pad 30b. In the present embodiment, the edge through vias ETHV may be spaced apart from the sub-stack structures ST1 and ST2. The edge through vias ETHV may be respectively connected to the electrode connection lines CL through third contacts CT3, which are disposed in the second upper insulating layer 208. Accordingly, the electrode layers EL1 and EL2 may be connected to the peripheral circuit structure PS (e.g., the decoder circuit 1110 of FIG. 1A). A via insulating pattern SP2 may be interposed between the edge through via ETHV and the planarization insulating layers 210 and 220 and between the edge through via ETHV and the etch stop layer 111.

The edge through vias ETHV may be formed of or include at least one of metallic materials (e.g., tungsten, aluminum, copper, titanium, and tantalum). The via insulating pattern SP2 may be formed of or include at least one of insulating materials (e.g., silicon oxide, silicon nitride, and silicon oxynitride).

Referring to FIGS. 2 and 3, a substrate ground region WR may be disposed in a portion of the second substrate 201 spaced apart from the edge through vias ETHV. The substrate ground region WR may be doped to have the same conductivity type as the second substrate 201 (e.g., the first conductivity type) and to have a higher doping concentration than that in the second substrate 201. A substrate contact plug WC may be provided in the connection region CNR to penetrate the first upper insulating layer 205 and the planarization insulating layers 210 and 220 and to be in contact with the substrate ground region WR.

The electrode connection lines CL may be covered with the third upper insulating layer 209. An outer terminal CP may be disposed on the third upper insulating layer 209. A fourth contact CT4 may be provided to penetrate the third and second upper insulating layers 209 and 208 and to connect the outer terminal CP to the substrate contact plug WC. A side surface of the substrate contact plug WC may be covered with a contact insulating pattern SP3.

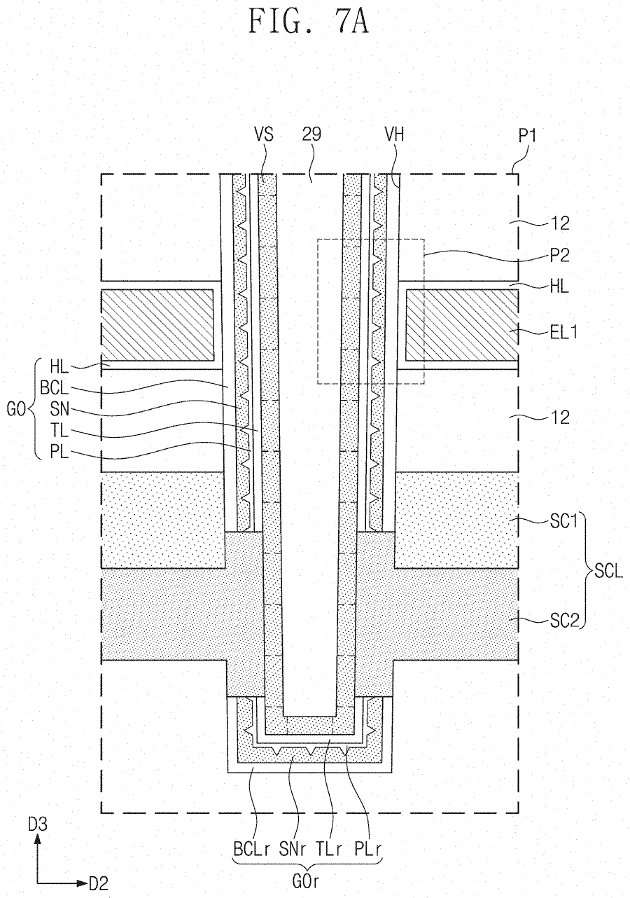

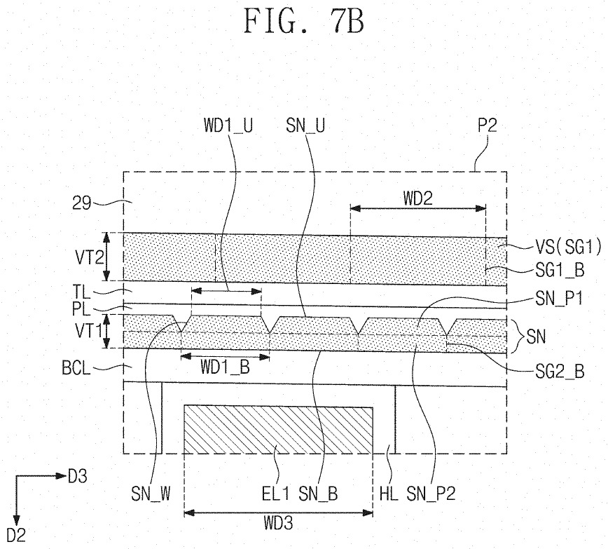

FIG. 7A is an enlarged sectional view illustrating a portion (e.g., ‘P1’ of FIG. 4) of a semiconductor device according to an embodiment of inventive concepts. FIG. 7B is an enlarged sectional view illustrating a portion (e.g., ‘P2’ of FIG. 7A) of a semiconductor device according to an embodiment of inventive concepts.

Referring to FIGS. 7A and 7B, the charge storing patterns SN according to the present embodiment may be connected to each other. Each of the charge storing patterns SN may include a first portion SN_P1 and a second portion SN_P2. In each charge storing pattern SN, the first and second portions SN_P1 and SN_P2 may be connected to form a single object. The second portions SN_P2 may be in contact with the blocking insulating layer. The second portions SN_P2 may be connected to each other. Accordingly, the charge storing patterns SN may be connected to each other, thereby serving as a charge storing layer SN.

Second boundaries SG2_B may exist between the second portions SN_P2. The first portions SN_P1 may be spaced apart from the blocking insulating layer. The first portions SN_P1 may be spaced apart from each other. Each of the first portions SN_P1 may have a width smaller than a width of a corresponding one of the second portions SN_P2. The side surface SN_W of the first portions SN_P1 may be inclined at an angle to a surface of the blocking insulating layer BCL. A mean value of the widths WD1_U of the top surfaces SN_U of the charge storing patterns SN may range from 3 nm to 10 nm.

As shown in FIG. 6, the first portions SN_P1 of the charge storing patterns SN may be two-dimensionally provided along the surface of the blocking insulating layer BCL. When viewed in a direction normal to the surface of the blocking insulating layer BCL, each of the first portions SN_P1 of the charge storing patterns SN may have a polygonal shape (e.g., rectangular, tetragonal, trapezoidal, pentagonal, hexagonal, heptagonal, and octagonal shapes). The variation coefficient (or dispersion/fluctuation rate) of the width WD1_U of the top surface SN_U of the charge storing patterns SN may range from 0.5-10%.

In the present embodiment, the first portions SN_P1 of the charge storing patterns SN may be spaced apart from each other. It may be possible to reduce the lateral/vertical charge loss, compared to the case that the charge storing patterns SN are completely connected to each other. In addition, the widths WD1_U of the first portions SN_P1 of the charge storing patterns SN may have uniform values whose variation coefficient (or dispersion/fluctuation rate) is less than 10%. Thus, it may be possible to improve uniformity and reliability characteristics in the data writing operation on the charge storing patterns SN.

The charge storing patterns SN may be covered with the passivation layer PL. The passivation layer PL may be formed of or include at least one of SiN, SiO, SiON, or metal oxide materials and may have a single- or multi-layered structure. The passivation layer PL may limit and/or prevent defects, such as dangling bonds, from being formed on surfaces of the charge storing patterns SN, and this may make it possible to reduce lateral/vertical charge loss. The passivation layer PL may be spaced apart from the blocking insulating layer BCL. Except for the above features, the semiconductor device in the present embodiment may be configured to have substantially the same or similar features to those described with reference to FIGS. 5A to 5D and 6.

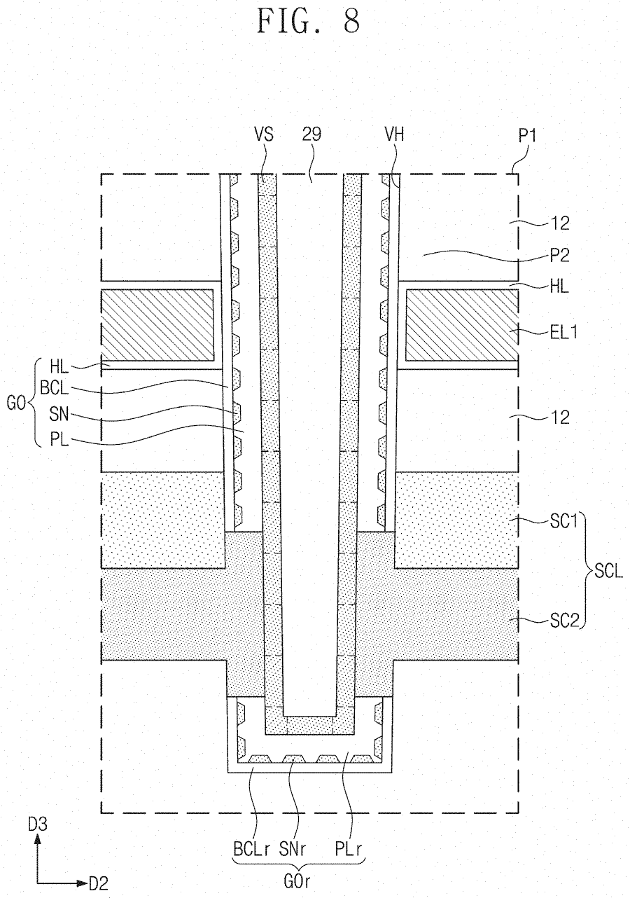

FIG. 8 is an enlarged sectional view illustrating a portion (e.g., ‘P1’ of FIG. 4) of a semiconductor device according to an embodiment of inventive concepts.

Referring to FIG. 8, the tunnel insulating layer TL of FIGS. 5A and 5B may not be provided in the gate insulating layer GO of the three-dimensional semiconductor memory device according to the present embodiment. In this case, the passivation layer PL may be used to function as the tunnel insulating layer TL. The passivation layer PL may be in contact with the vertical semiconductor pattern VS as well as the charge storing patterns SN. Except for the above features, the semiconductor device in the present embodiment may be configured to have substantially the same or similar features to those described with reference to FIGS. 5A, 5B, and 6.

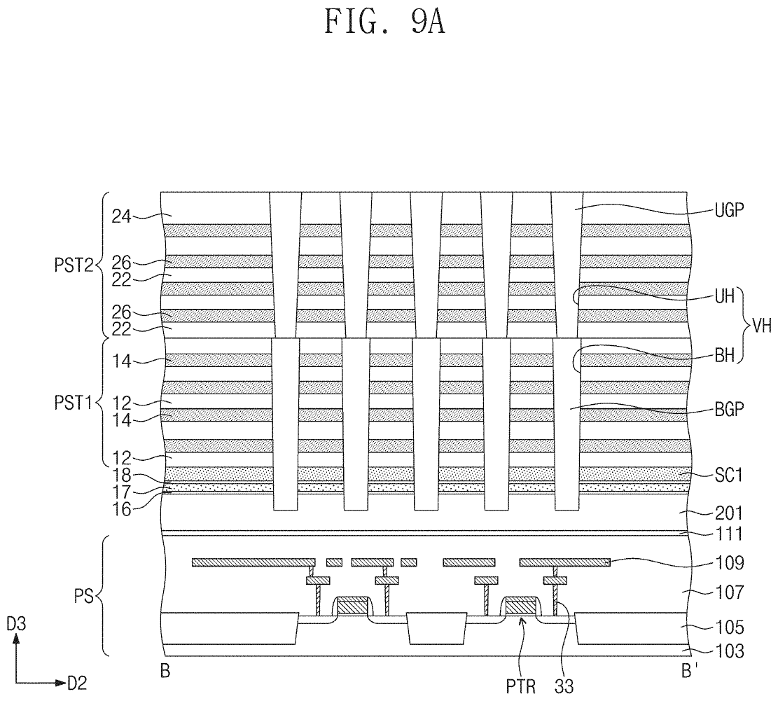

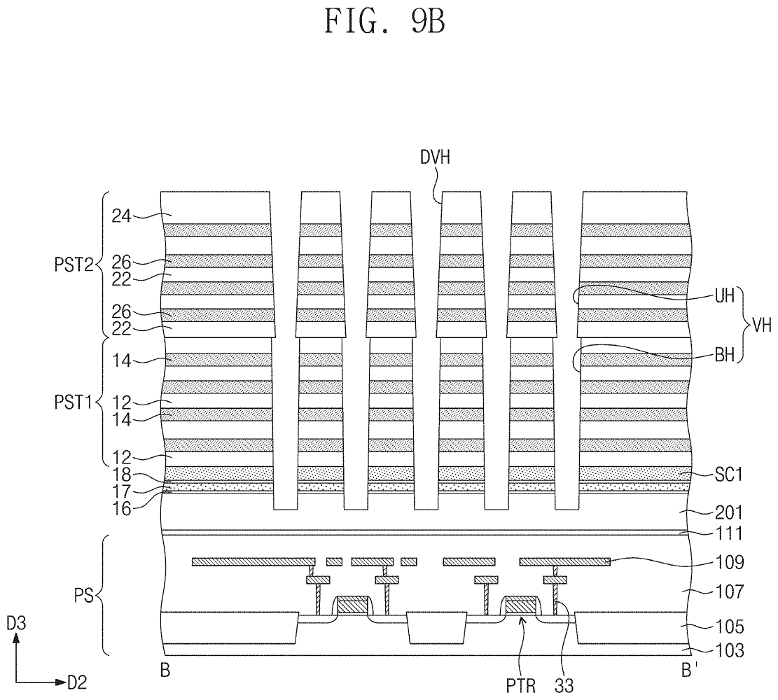

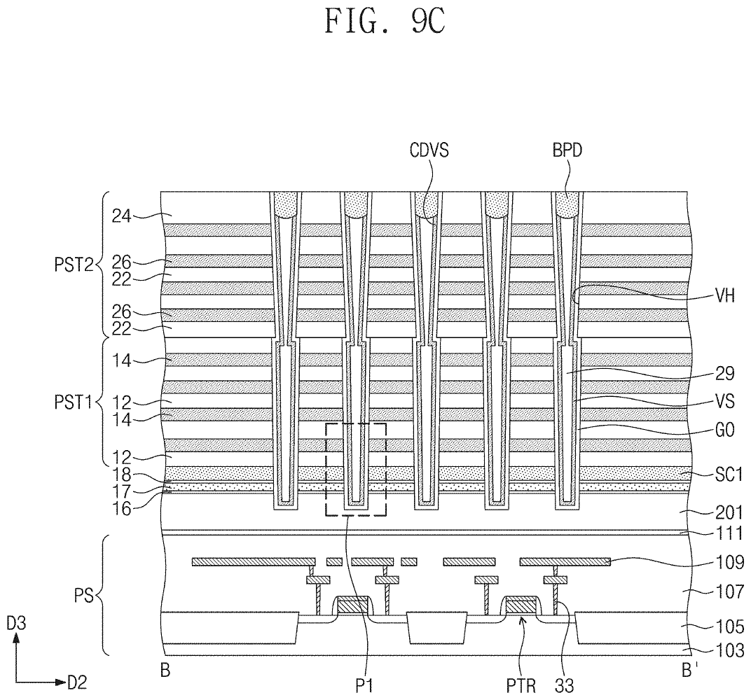

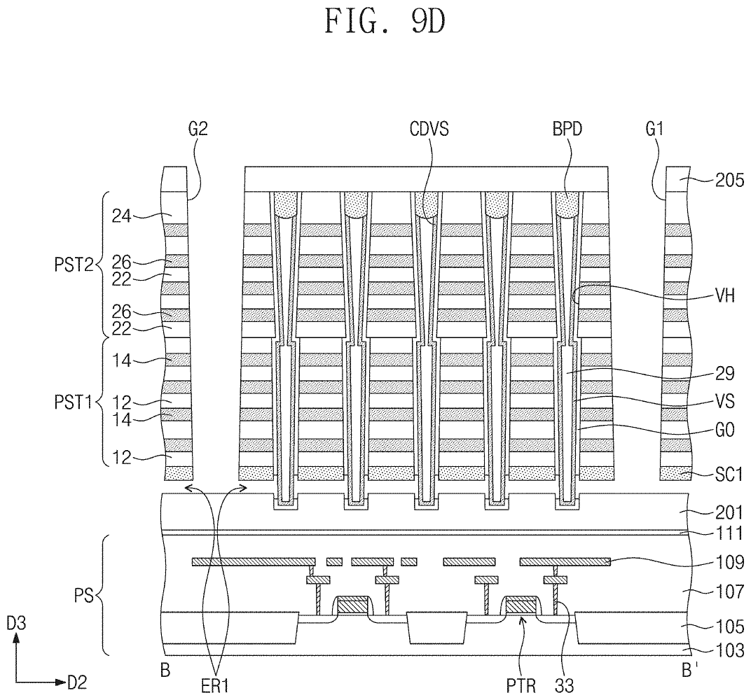

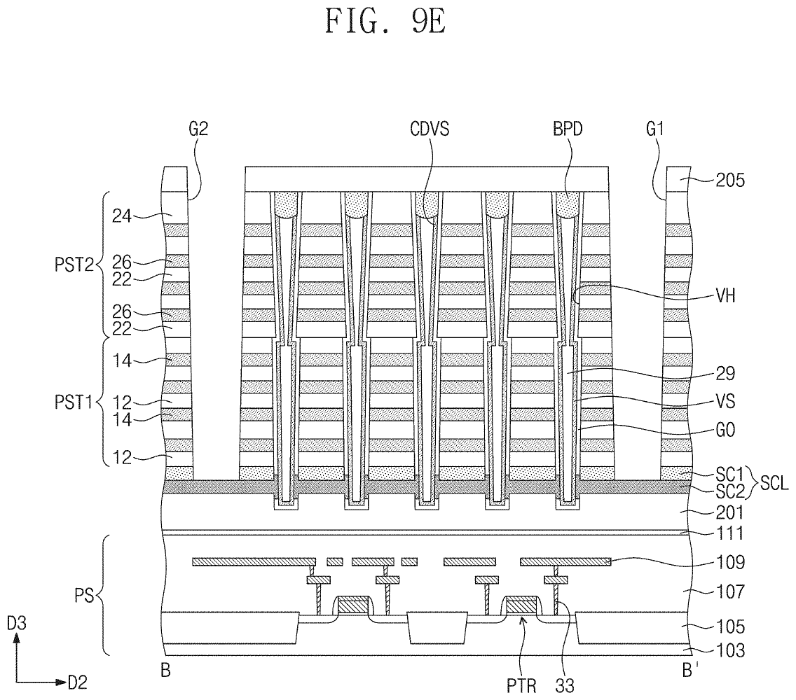

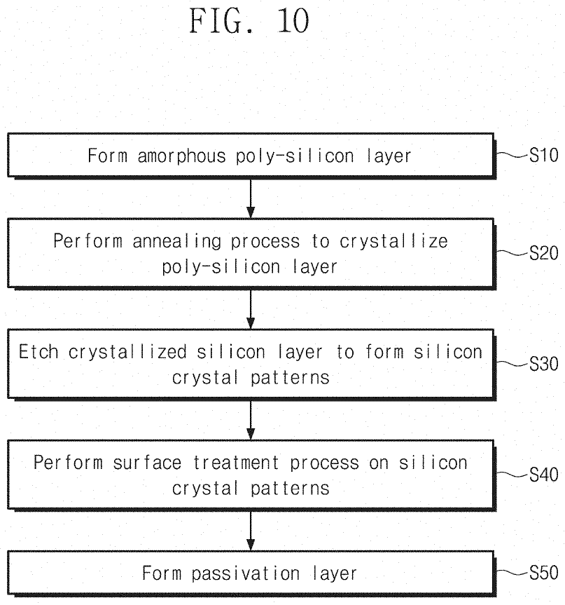

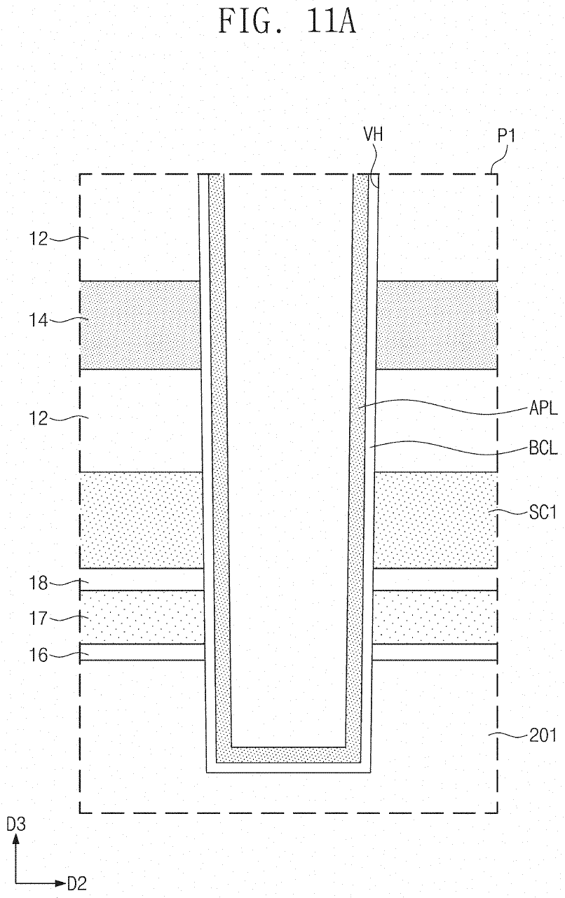

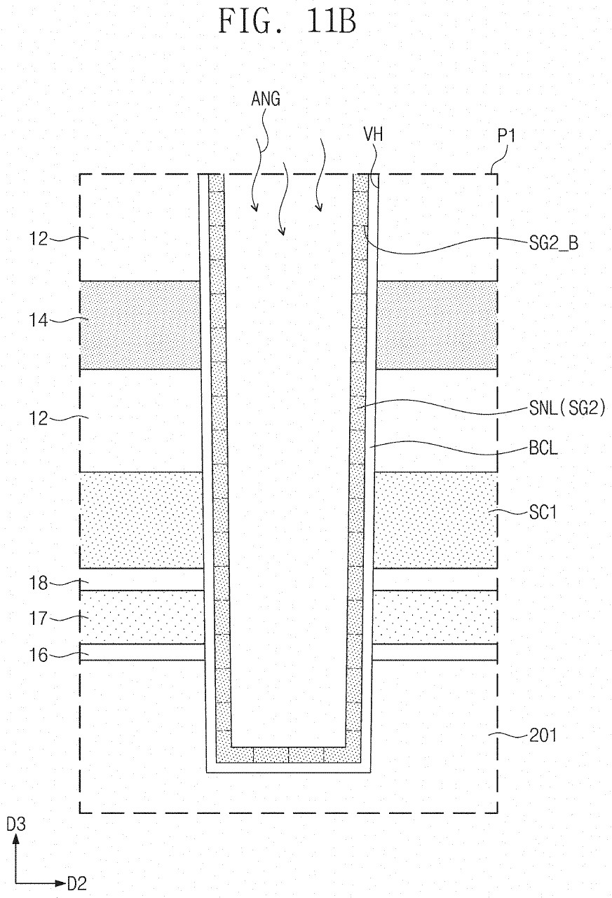

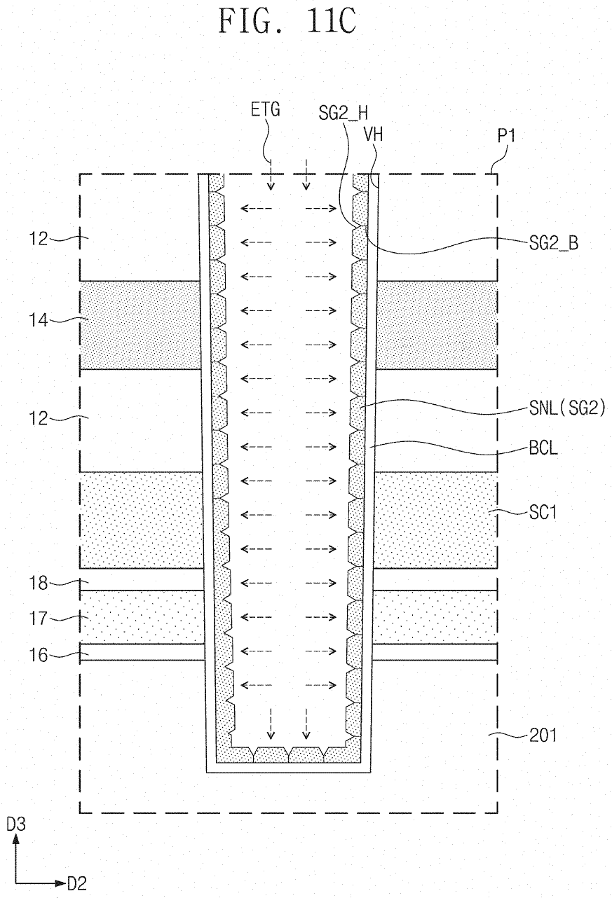

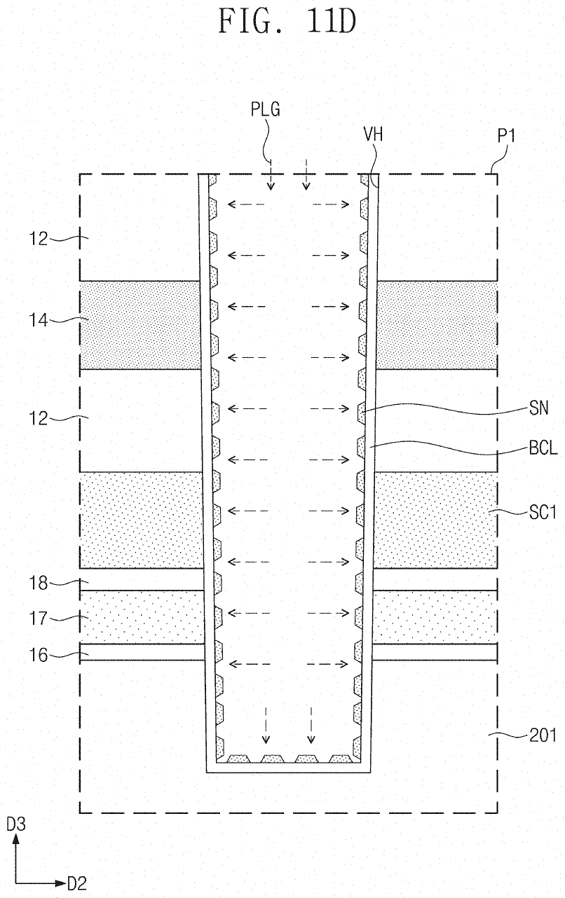

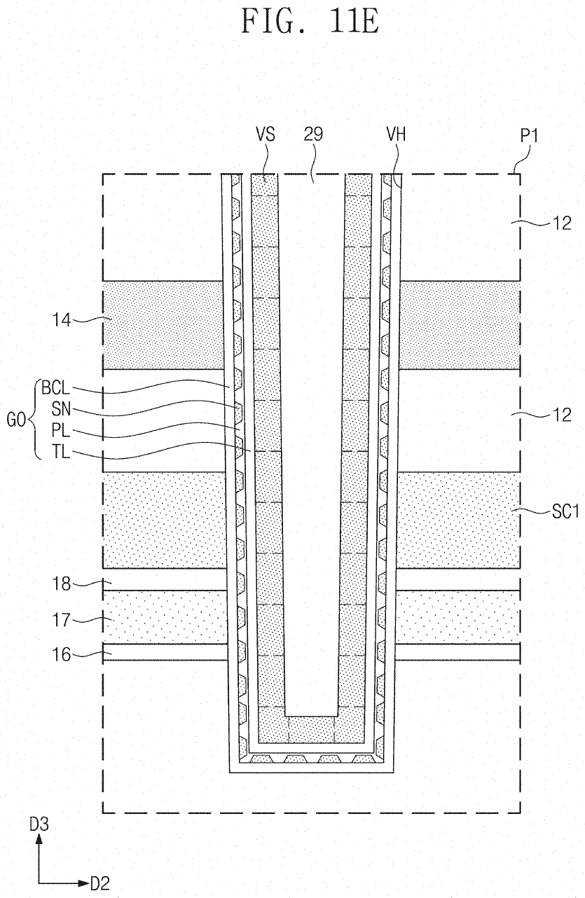

FIG. 9A to 9E are sectional views illustrating a process of fabricating a three-dimensional semiconductor memory device having the section of FIG. 4. FIG. 10 is a process flow chart illustrating a process of forming charge storing patterns, according to an embodiment of inventive concepts. FIG. 11A to 11E are sectional views illustrating a portion (e.g., ‘P1’ of FIG. 9C) during the fabrication process. FIG. 11E corresponds to an enlarged sectional view of the portion ‘P1’ of FIG. 9C.

Referring to FIG. 9A, the peripheral circuit structure PS may be fabricated. In detail, the device isolation layer 105 may be formed in the first substrate 103 to delimit active regions. The transistors PTR may be formed on the active regions. The peripheral interlayer insulating layer 107, which is composed of a plurality of layers, may be formed to cover the transistors PTR, and the peripheral contacts 33 and the peripheral lines 109 may be formed in the peripheral interlayer insulating layer 107. The peripheral conductive pads 30b of FIG. 3 may be formed at the topmost portion of the peripheral circuit structure PS. The etch stop layer 111 may be formed on the peripheral circuit structure PS.

Next, the second substrate 201 may be formed on the etch stop layer 111. The second substrate 201 may be formed by forming a semiconductor epitaxial layer or by attaching a single crystalline semiconductor substrate to the etch stop layer 111. The second substrate 201 may be referred to as a semiconductor layer. The second substrate 201 may be doped to have, for example, the first conductivity type. The substrate ground region WR of FIG. 3 may be formed in the second substrate 201. The substrate ground region WR may be formed by doping the second substrate 201 with impurities of the first conductivity type and may have an impurity concentration that is higher than that of the second substrate 201. The second substrate 201 may include the cell array region CAR and the connection region CNR, as shown in FIG. 2.

A first buffer layer 16, a first sacrificial layer 17, a second buffer layer 18, and the first source pattern SC1 may be sequentially stacked on the second substrate 201. A first preliminary stack structure PST1 may be formed by alternately and repeatedly stacking first electrode interlayer insulating layers 12 and second sacrificial layers 14 on the first source pattern SC1. The first source pattern SC1 may be a doped poly-silicon layer. In an embodiment, the first and second buffer layers 16 and 18 and the electrode interlayer insulating layers 12 may include a silicon oxide layer. The first sacrificial layer 17 may be formed of or include a material having an etch selectivity with respect to all of the first and second buffer layers 16 and 18, the first electrode interlayer insulating layers 12, the first source pattern SC1, and the second sacrificial layers 14. For example, the second sacrificial layers 14 may include a silicon nitride layer. The first sacrificial layer 17 may be a silicon germanium layer or a silicon oxynitride layer. Alternatively, the first sacrificial layer 17 may be a doped poly-silicon layer, which is doped to have a doping concentration different from the first source pattern SC1.

Trimming processes and anisotropic etching processes may be alternately and repeatedly performed to form end portions of the first electrode interlayer insulating layers 12 and the second sacrificial layers 14 in the staircase structure on the connection region CNR, as shown in FIG. 3. Here, the first buffer layer 16, the first sacrificial layer 17, the second buffer layer 18, and the first source pattern SC1 may also be partially etched to expose the top surface of the second substrate 201. The first planarization insulating layer 210 may be formed to cover the end portions of the first preliminary stack structure PST1, and then, a chemical mechanical polishing (CMP) process may be performed on the first planarization insulating layer 210.

A plurality of bottom holes BH may be formed by partially etching the first preliminary stack structure PST1, the first source pattern SC1, the second buffer layer 18, the first sacrificial layer 17, the first buffer layer 16, and the second substrate 201 on the cell array region CAR. Bottom sacrificial gapfill patterns BGP may be formed to fill the bottom holes BH, respectively. The bottom sacrificial gapfill pattern BGP may be formed of or include a material having an etch selectivity with respect to all of the first electrode interlayer insulating layers 12, the second sacrificial layers 14, the first source pattern SC1, the second buffer layer 18, the first sacrificial layer 17, the first buffer layer 16, and the second substrate 201. For example, the bottom sacrificial gapfill pattern BGP may be formed of or include spin-on-hardmask (SOH) materials, amorphous carbon layer (ACL) materials, or SiGe.

A second preliminary stack structure PST2 may be formed by alternately and repeatedly stacking the second electrode interlayer insulating layers 22 and 24 and third sacrificial layers 26 on the first preliminary stack structure PST1 and the first planarization insulating layer 210. The second electrode interlayer insulating layers 22 and 24 may be formed of or include the same material as the first electrode interlayer insulating layers 12. The third sacrificial layers 26 may be formed of or include the same material as the second sacrificial layers 14.

Trimming processes and anisotropic etching processes may be alternately and repeatedly performed to form end portions of the second electrode interlayer insulating layers 22 and 24 and the third sacrificial layers 26 in the staircase structure on the connection region CNR, as shown in FIG. 3. The second planarization insulating layer 220 may be formed to cover the end portions of the second preliminary stack structure PST2, and then, a chemical mechanical polishing (CMP) process may be performed on the second planarization insulating layer 220. Thereafter, upper holes UH may be formed by etching the second preliminary stack structure PST2 on the cell array region CAR and a dummy region DR, and in an embodiment, the upper holes UH may be formed to expose the sacrificial gapfill patterns BGP, respectively. Next, each of the upper holes UH may be filled with an upper sacrificial gapfill pattern UGP. The upper sacrificial gapfill pattern UGP may be formed of or include at least one of spin-on-hardmask (SOH) materials, amorphous carbon layer (ACL) materials, or SiGe.

The upper holes UH and the bottom holes BH, which are overlapped with each other, may constitute vertical holes VH and dummy vertical holes DVH. The dummy vertical holes DVH may be disposed between the vertical holes VH and may be arranged in the first direction D1.

Referring to FIG. 9B, the upper and bottom sacrificial gapfill patterns UGP and BGP may be removed from the vertical holes VH and the dummy vertical holes DVH to expose inner surfaces of the vertical holes VH and the dummy vertical holes DVH.

Referring to FIG. 9C, the gate insulating layer GO may be formed in the vertical holes VH and the dummy vertical holes DVH. For this, as shown in FIG. 11A, the blocking insulating layer BCL may be conformally formed on the first and second preliminary stack structures PST1 and PST2, in which the vertical holes VH and the dummy vertical holes DVH are formed. The blocking insulating layer BCL may be formed by, for example, an atomic layer deposition (ALD) method or a chemical vapor deposition (CVD) method.

Referring to FIGS. 10 and 11A, an amorphous poly-silicon layer APL may be formed on the blocking insulating layer BCL (in S10). The amorphous poly-silicon layer APL may be formed by depositing a silicon layer using an atomic layer deposition (ALD) or a chemical vapor deposition (CVD) method. The deposition of the amorphous poly-silicon layer APL may be performed at temperature of 300-800° C. In an embodiment, at least one of monosilane (SiH₄), disilane (Si₂H₆), trisilane (Si₃H₈), tetrasilane (Si₄H₁₀), neopentasilane (Si₅H₁₂), diisoprophylamino silane (H₃Si[N{(CH)(CH₃)₂}]), bis-diethylamino silane (H₂Si((N(C₂H₅)₂)₂), tetrakis(dimethylamino)silane (Si[N(CH₃)₂]₄) may be used as a source gas supplied during the deposition of the amorphous poly-silicon layer APL. During the deposition of the amorphous poly-silicon layer APL, the amorphous poly-silicon layer APL may be doped with impurities in an in-situ manner. The impurities may be phosphorus, arsenic, or boron.

Referring to FIGS. 10 and 11B, an annealing process ANG of crystallizing the amorphous poly-silicon layer APL may be performed to form a crystallized silicon layer SNL (in S20). The annealing process ANG may be performed at temperature of 500 to 1100° C. The crystallized silicon layer SNL may be composed of a plurality of second silicon crystal grains SG2. Second boundaries SG2_B or second crystal grain boundaries may exist between the second silicon crystal grains SG2. The longer the process time and the higher the process temperature of the annealing process ANG, the larger the size of the second silicon crystal grains SG2. In the case where the amorphous poly-silicon layer APL is formed to have an increased thickness (in S10), the size of the second silicon crystal grains SG2 may be increased.

Referring to FIGS. 10, 11C, and 11D, the crystallized silicon layer SNL may be etched to form silicon crystal patterns SN (in S30). Here, an etchant ETG may be supplied to the crystallized silicon layer SNL through the vertical holes VH and the dummy vertical holes DVH. The etching process may be isotropically performed in a dry or wet manner. The etchant may include at least one of, for example, Cl₂ or HCl.

In an embodiment, the etching process may be a gas phase etch (GPE) process. In the etching process, the etchants may more easily infiltrate to the second boundaries SG2_B between the second silicon crystal grains SG2 than to the top surfaces of the second silicon crystal grains SG2. This is because the second boundaries SG2_B between the second silicon crystal grains SG2 have an amorphous structure and a bonding strength between silicon atoms is relatively weaker in the second boundaries SG2_B between the second silicon crystal grains SG2 than in the second silicon crystal grains SG2. Thus, the second boundaries SG2_B between the second silicon crystal grains SG2 may be etched at a higher etch rate, and in this case, grooves SG2_H may be formed near the second boundaries SG2_B between the second silicon crystal grains SG2, as shown in FIG. 11C. As the etching process is further performed, the silicon crystal patterns SN, which are spaced apart from each other, may be formed, as shown in FIG. 11D. The silicon crystal patterns SN may be referred to as the charge storing patterns SN. In the gas phase etch (GPE) process using the etchant, it may be possible to realize an excellent etch selectivity between an amorphous silicon layer and the blocking insulating layer BCL, and thus, the second boundaries SG2_B between the second silicon crystal grains SG2 may be selectively etched without damage of the blocking insulating layer BCL. Accordingly, it may be possible to effectively form the silicon crystal patterns SN, which are spaced apart from each other.

Furthermore, by adjusting process conditions (e.g., temperature and pressure) in the etching process, the silicon crystal patterns SN may be formed to have uniform size, thickness, and distance. For example, in the case where the temperature and pressure in the etching process are increased, the size of the silicon crystal patterns SN may be reduced and the distance between the silicon crystal patterns SN may be increased.

According to an embodiment of inventive concepts, the charge storing patterns may be formed by forming an amorphous poly-silicon layer, crystallizing the poly-silicon layer through an annealing process, and performing an etching process to etch a boundary between silicon crystal grains. In this case, the charge storing patterns may be formed to have uniform size, thickness, and distance. Accordingly, it may be possible to limit and/or prevent or reduce a position-dependent data writing/erasing error in a three-dimensional semiconductor memory device and thereby to improve reliability of the three-dimensional semiconductor memory device.

As described with reference to FIGS. 7A and 7B, the second silicon crystal grains SG2 may not be separated from each other depending on the process condition of the etching process, and in this case, the charge storing patterns SN may be formed such that the second portions SN_P2 are connected to each other.

Referring to FIGS. 10 and 11D, a surface treatment process may be performed on the silicon crystal patterns SN (in S40). The surface treatment process S40 may be an oxidation process or nitridation process using plasma PLG or solution. The plasma PLG may be oxygen plasma or nitrogen plasma. The solution may be, for example, ozone water. As a result of the surface treatment process S40, the capping layer CPL may be formed on surfaces of the silicon crystal patterns SN, as shown in FIG. 5C or 5D. The surface treatment process S40 may be omitted.

Referring to FIGS. 10 and 11E, the passivation layer PL may be formed (in S50). The passivation layer PL may be formed by an ALD method or a CVD method. The passivation layer PL may be formed of or include at least one of SiN, SiO, SiON, or metal oxide materials and may have a single- or multi-layered structure.

Referring to FIGS. 9C and 11E, the tunnel insulating layer TL may be formed on the passivation layer PL. The tunnel insulating layer TL may be formed by an ALD or CVD process. As a result, the gate insulating layer GO may be formed. The cell vertical pattern VS and a center dummy vertical pattern CDVS may be formed on the gate insulating layer GO. In an embodiment, the vertical semiconductor pattern VS and the center dummy vertical pattern CDVS may be formed by an ALD or CVD process. The vertical semiconductor pattern VS and the center dummy vertical pattern CDVS may be formed of a doped or undoped amorphous poly-silicon layer. An annealing process may be further performed to crystallize the amorphous poly-silicon layers of the vertical semiconductor pattern VS and the center dummy vertical pattern CDVS. In an embodiment, the annealing process may be omitted, and in this case, the amorphous poly-silicon layers of the vertical semiconductor pattern VS and the center dummy vertical pattern CDVS may be crystallized by heat supplied during subsequent processes. Accordingly, the vertical semiconductor pattern VS and the center dummy vertical pattern CDVS may have the first silicon crystal grains SG1, as described with reference to FIG. 5B. The amorphous poly-silicon layers of the vertical semiconductor pattern VS and the center dummy vertical pattern CDVS may be formed to be thicker than the amorphous poly-silicon layer APL, which is used for the charge storing pattern SN of FIG. 11A. Thus, the width WD2 of the first silicon crystal grains SG1 may be larger than the width WD1 of the charge storing pattern SN, as shown in FIG. 5B.

The vertical holes VH may be filled with the insulating gapfill pattern 29. An upper portion of the vertical semiconductor pattern VS may be removed to form an empty region, and then, the bit line pad BPD may be formed by filling the empty region with a doped silicon layer.

Referring to FIGS. 9C and 9D, the first upper insulating layer 205 may be stacked on the second preliminary stack structure PST2. The first and second grooves G1 and G2 exposing the first sacrificial layer 17 may be formed by sequentially etching the first upper insulating layer 205, the second preliminary stack structure PST2, the first preliminary stack structure PST1, the first source pattern SC1, and the second buffer layer 18. A first empty space ER1 may be formed by removing the second buffer layer 18, the first sacrificial layer 17, and the first buffer layer 16 through the first and second grooves G1 and G2.

When the first empty space ER1 is formed, a portion of the gate insulating layer GO may be removed to expose side surfaces of the cell vertical pattern VS, the center dummy vertical pattern CDVS, and the edge dummy vertical pattern EDVS of FIG. 3. When the first empty space ER1 is formed, the vertical semiconductor pattern VS, the vertical conductive pattern CSPG, and the edge dummy vertical pattern EDVS of FIG. 3 may support a preliminary cell array structure PCS and may be used to limit and/or prevent the preliminary cell array structure PCS from collapsing.

Referring to FIGS. 9D and 9E, a second source layer may be conformally formed to fill the first empty space ER1 through the first and second grooves G1 and G2, and then, an anisotropic etching process may be performed to remove the second source layer from the first and second grooves G1 and G2 and to leave a portion of the second source layer, which is used as the second source pattern SC2, in the first empty space ER1. Accordingly, the first and second source patterns SC1 and SC2 may constitute the source structure SCL.

Referring to FIGS. 9E and 4, second empty spaces may be formed between the electrode interlayer insulating layers 12, 22, and 24 by removing the second sacrificial layers 14 and the third sacrificial layers 26 through the first and second grooves G1 and G2. A conductive layer may be conformally deposited to fill the second empty spaces through the first and second grooves G1 and G2. Next, an anisotropic etching process may be performed to remove the conductive layer from the first and second grooves G1 and G2 and to form the electrode layers EL1 and EL2 in the second empty spaces. As a result, the first and second sub-stack structures ST1 and ST2 may be formed. The high-k dielectric layer HL of FIG. 5A may be conformally formed before the formation of the conductive layer for the electrode layers EL1 and EL2. An insulating layer may be formed to fill the first and second grooves G1 and G2 and may be etched/planarized to form the first and second insulating isolation lines SL1 and SL2. A subsequent process may be performed (e.g., in a typical manner) to fabricate the three-dimensional semiconductor memory device described with reference to FIGS. 2 to 4.

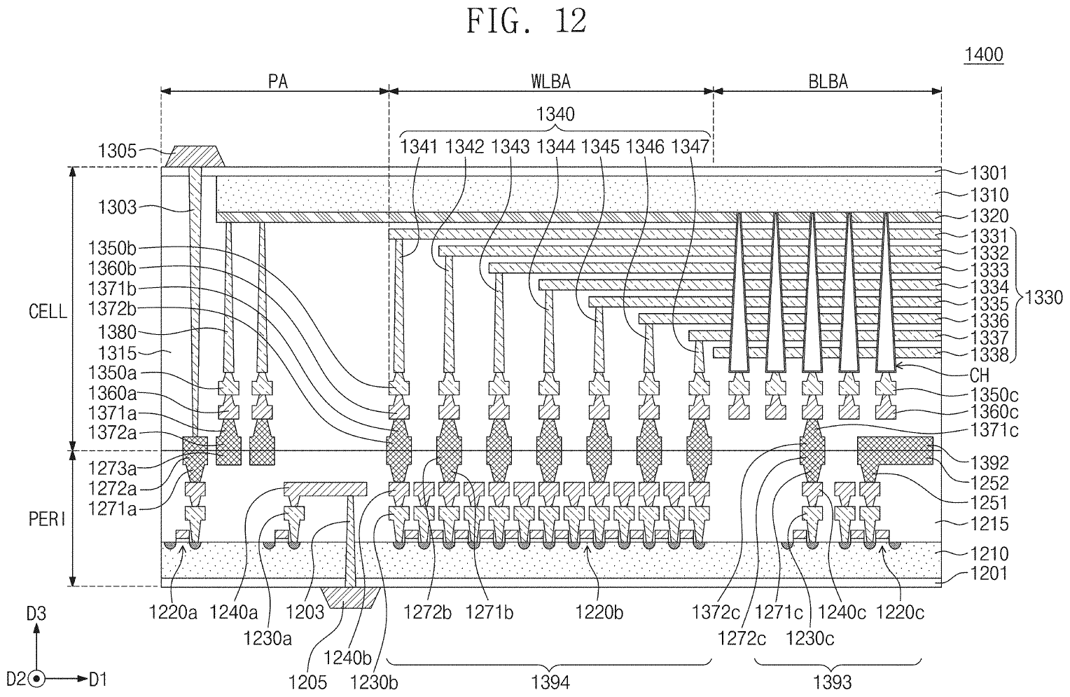

FIG. 12 is a sectional view illustrating a semiconductor device according to an embodiment of inventive concepts.

Referring to FIG. 12, a memory device 1400 may have a chip-to-chip (C2C) structure. For the C2C structure, an upper chip including a cell array structure CELL may be fabricated on a first wafer, a lower chip including a peripheral circuit structure PERI may be fabricated on a second wafer different from the first wafer, and the upper chip and the lower chip may be connected to each other in a bonding manner. The bonding manner may mean a way of electrically connecting a bonding metal formed in the uppermost metal layer of the upper chip to a bonding metal formed in the uppermost metal layer of the lower chip. For example, in the case where the bonding metal is formed of copper (Cu), the bonding manner may be a Cu-to-Cu bonding manner, but in an embodiment, aluminum (Al) or tungsten (W) may be used as the bonding metal.

Each of the peripheral circuit structure PERI and the cell array structure CELL of the memory device 1400 may include an outer pad bonding region PA, a word line bonding region WLBA, and a bit line bonding region BLBA.

The peripheral circuit structure PERI may include a first substrate 1210, an interlayer insulating layer 1215, a plurality of circuit devices 1220a, 1220b, and 1220c formed on the first substrate 1210, first metal layers 1230a, 1230b, and 1230c connected to the circuit devices 1220a, 1220b, and 1220c, respectively, and second metal layers 1240a, 1240b, and 1240c formed on the first metal layers 1230a, 1230b, and 1230c. In an embodiment, the first metal layers 1230a, 1230b, and 1230c may be formed of or include a material (e.g., tungsten) having relatively high electric resistivity, and the second metal layers 1240a, 1240b, and 1240c may be formed of or include a material (e.g., copper) having relatively low electric resistivity.

Although only the first metal layers 1230a, 1230b, and 1230c and the second metal layers 1240a, 1240b, and 1240c are illustrated and described in the present specification, inventive concepts is not limited thereto and at least one metal layer may be further formed on the second metal layers 1240a, 1240b, and 1240c. At least one of the additional metal layers, which are formed on the second metal layers 1240a, 1240b, and 1240c, may be formed of a material (e.g., aluminum), which has lower electric resistivity than the material (e.g., copper) of the second metal layers 1240a, 1240b, and 1240c.

The interlayer insulating layer 1215 may be disposed on the first substrate 1210 to cover the circuit devices 1220a, 1220b, and 1220c, the first metal layers 1230a, 1230b, and 1230c, and the second metal layers 1240a, 1240b, and 1240c and may be formed of or include at least one of insulating materials (e.g., silicon oxide and silicon nitride).

Lower bonding metals 1271b and 1272b may be formed on the second metal layer 1240b of the word line bonding region WLBA. In the word line bonding region WLBA, the lower bonding metals 1271b and 1272b of the peripheral circuit structure PERI may be electrically connected to upper bonding metals 1371b and 1372b of the cell array structure CELL in a bonding manner, and the lower bonding metals 1271b and 1272b and the upper bonding metals 1371b and 1372b may be formed of or include at least one of aluminum, copper, or tungsten.

The cell array structure CELL may correspond to the cell array structure CS described with reference to FIGS. 2 to 8. The cell array structure CELL may include at least one memory block. The cell array structure CELL may include a second substrate 1310 and a common source line 1320. A plurality of word lines 1331-1338 (1330) may be stacked on the second substrate 1310 in a third direction (D3) that is perpendicular to a top surface of the second substrate 1310. String selection lines and a ground selection line may be respectively disposed on and below the word lines 1330; that is, the word lines 1330 may be disposed between the string selection lines and the ground selection line.

In the bit line bonding region BLBA, a channel structure CH may be provided to extend in the third direction (D3) perpendicular to a top surface of the second substrate 1310 and to penetrate the word lines 1330, the string selection lines, and the ground selection line. The channel structure CH may include a data storage layer, a channel layer, and an insulating gapfill layer, and the channel layer may be electrically connected to a first metal layer 1350c and a second metal layer 1360c. For example, the first metal layer 1350c may be a bit line contact, and the second metal layer 1360c may be a bit line. In an embodiment, the bit line 1360c may be extended in a second direction (D2) parallel to the top surface of the second substrate 1310.

In an embodiment shown in FIG. 12, a region provided with the channel structure CH and the bit line 1360c may be defined as the bit line bonding region BLBA. In the bit line bonding region BLBA, the bit lines 1360c may be electrically connected to the circuit devices 1220c, which are provided in the peripheral circuit structure PERI to constitute a page buffer 1393. As an example, the bit lines 1360c may be connected to the peripheral circuit structure PERI through upper bonding metals 1371c and 1372c, and the upper bonding metals 1371c and 1372c may be connected to lower bonding metals 1271c and 1272c, which are connected to the circuit devices 1220c of the page buffer 1393.

In the word line bonding region WLBA, the word lines 1330 may be extended in a first direction (D1), which is perpendicular to the second direction (D2) and is parallel to the top surface of the second substrate 1310, and may be connected to a plurality of cell contact plugs 1341-1347 (1340). The cell contact plugs 1341-1347 or 1340 may have the same shape as the cell contact plug CC of FIG. 3.

The cell contact plugs 1340 may be connected to pads of the word lines 1330, which are extended to have different lengths from each other in the first direction (D1). A first metal layer 1350b and a second metal layer 1360b may be sequentially connected to upper portions of the cell contact plugs 1340 connected to the word lines 1330. In the word line bonding region WLBA, the cell contact plugs 1340 may be connected to the peripheral circuit structure PERI through the upper bonding metals 1371b and 1372b of the cell array structure CELL and the lower bonding metals 1271b and 1272b of the peripheral circuit structure PERI.

In the peripheral circuit structure PERI, the cell contact plugs 1340 may be electrically connected to the circuit devices 1220b constituting a row decoder 1394. In an embodiment, an operation voltage of the circuit devices 1220b constituting the row decoder 1394 may be different from an operation voltage of the circuit devices 1220c constituting the page buffer 1393. As an example, the operation voltage of the circuit devices 1220c constituting the page buffer 1393 may be higher than the operation voltage of the circuit devices 1220b constituting the row decoder 1394.

A common source line contact plug 1380 may be disposed in the outer pad bonding region PA. The common source line contact plug 1380 may be formed of a conductive material (e.g., metals, metal compounds, or polysilicon) and may be electrically connected to the common source line 1320. A first metal layer 1350a and a second metal layer 1360a may be sequentially stacked on the common source line contact plug 1380. A region, in which the common source line contact plug 1380, the first metal layer 1350a, and the second metal layer 1360a are provided, may be defined as the outer pad bonding region PA.

Meanwhile, input/output pads 1205 and 1305 may be disposed in the outer pad bonding region PA. Referring to FIG. 12, a lower insulating layer 1201 may be formed below the first substrate 1210 to cover the bottom surface of the first substrate 1210, and a first input/output pad 1205 may be formed on the lower insulating layer 1201. The first input/output pad 1205 may be connected to at least one of the circuit devices 1220a, 1220b, and 1220c of the peripheral circuit structure PERI through a first input/output contact plug 1203 and may be separated from the first substrate 1210 by the lower insulating layer 1201. In addition, a sidewall insulating layer (not shown) may be disposed between the first input/output contact plug 1203 and the first substrate 1210 to electrically separate the first input/output contact plug 1203 from the first substrate 1210.

Referring to FIG. 12, an upper insulating layer 1301 may be formed on the second substrate 1310 to cover the top surface of the second substrate 1310, and a second input/output pad 1305 may be disposed on the upper insulating layer 1301. The second input/output pad 1305 may be connected to at least one of the circuit devices 1220a, 1220b, and 1220c of the peripheral circuit structure PERI through a second input/output contact plug 1303. In an embodiment, the second input/output pad 1305 may be electrically connected to the circuit device 1220a.

In an embodiment, the second substrate 1310 and the common source line 1320 may not be disposed in a region provided with the second input/output contact plug 1303. In addition, the second input/output pad 1305 may not be overlapped with the word lines 1330 in the third direction (D3). Referring to FIG. 12, the second input/output contact plug 1303 may be separated from the second substrate 1310 in a direction parallel to the top surface of the second substrate 1310, may penetrate an interlayer insulating layer 1315 of the cell array structure CELL, and may be connected to the second input/output pad 1305.

In an embodiment, the first input/output pad 1205 and the second input/output pad 1305 may be selectively formed. As an example, the memory device 1400 may be configured to include only the first input/output pad 1205, which is provided on the first substrate 1210, or to include only the second input/output pad 1305, which is provided on the second substrate 1310. Alternatively, the memory device 1400 may be configured to include both of the first and second input/output pads 1205 and 1305.

A metal pattern, which is used as a dummy pattern, may be provided in the uppermost metal layer of the outer pad bonding region PA and the bit line bonding region BLBA, which are included in each of the cell array structure CELL and the peripheral circuit structure PERI, or may not be provided in the uppermost metal layer.

The memory device 1400 may include an upper metal pattern 1372a and a lower metal pattern 1273a, which are provided in the outer pad bonding region PA, and here, the lower metal pattern 1273a may be formed in the uppermost metal layer of the peripheral circuit structure PERI to correspond to the upper metal pattern 1372a, which is formed in the uppermost metal layer of the cell array structure CELL, or to have the same shape as the upper metal pattern 1372a of the cell array structure CELL. The lower metal pattern 1273a, which is formed in the uppermost metal layer of the peripheral circuit structure PERI, may not be connected to any contact plug in the peripheral circuit structure PERI. Similarly, in the outer pad bonding region PA, the upper metal pattern 1372a may be formed in the uppermost metal layer of the cell array structure CELL to correspond to the lower metal pattern 1273a, which is formed in the uppermost metal layer of the peripheral circuit structure PERI, and in this case, the upper metal pattern 1372a may have the same shape as the lower metal pattern 1273a of the peripheral circuit structure PERI.

The lower bonding metals 1271b and 1272b may be formed on the second metal layer 1240b of the word line bonding region WLBA. In the word line bonding region WLBA, the lower bonding metals 1271b and 1272b of the peripheral circuit structure PERI may be electrically connected to the upper bonding metals 1371b and 1372b of the cell array structure CELL in a bonding manner.

Furthermore, in the bit line bonding region BLBA, an upper metal pattern 1392 may be formed in the uppermost metal layer of the cell array structure CELL to correspond to a lower metal pattern 1252, which is formed in the uppermost metal layer of the peripheral circuit structure PERI, and in this case, the upper metal pattern 1392 may have the same shape as the lower metal pattern 1252 of the peripheral circuit structure PERI. In an embodiment, any contact plug may not be formed on the upper metal pattern 1392, which is formed in the uppermost metal layer of the cell array structure CELL.

In a three-dimensional semiconductor memory device according to an embodiment of inventive concepts and an electronic system including the same, charge storing patterns may be provided to be spaced apart from each other. In this case, it may be possible to reduce lateral/vertical charge loss, compared to the case that the charge storing patterns are connected to each other. Furthermore, the charge storing patterns may be formed to have uniform size, thickness, and distance, and thus, it may be possible to perform data writing and erasing operations in a highly uniform and reliable manner. In addition, a capping layer and/or a passivation layer covering the charge storing patterns may be further provided to limit and/or prevent defects, such as dangling bonds, from being formed on surfaces of the charge storing patterns and thus, this may make it possible to reduce lateral/vertical charge loss. Accordingly, it may be possible to improve the reliability of the three-dimensional semiconductor memory device.

In a method of fabricating a three-dimensional semiconductor memory device according to an embodiment of inventive concepts, the charge storing patterns may be formed by forming an amorphous poly-silicon layer, crystallizing the poly-silicon layer through an annealing process, and performing an etching process to etch a boundary between silicon crystal grains. In this case, the charge storing patterns may be formed to have uniform size, thickness, and distance. Accordingly, a highly-reliable three-dimensional semiconductor memory device may be fabricated.

One or more elements described above may be implemented using processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, a programmable logic unit, a microprocessor, application-specific integrated circuit (ASIC), etc. The processing circuitry may include a memory such as a volatile memory device (e.g., SRAM, DRAM, SDRAM) and/or a non-volatile memory (e.g., flash memory device, phase-change memory, ferroelectric memory device).

While some example embodiments of inventive concepts have been particularly shown and described, it will be understood by one of ordinary skill in the art that variations in form and detail may be made therein without departing from the spirit and scope of the attached claims. For example, features and/or aspects in embodiments of FIGS. 1A to 12 may be combined with each other.

1. A three-dimensional semiconductor memory device, comprising:
a stack structure including electrode layers and electrode interlayer insulating layers alternately stacked on a substrate;
vertical semiconductor patterns penetrating the stack structure; and
a gate insulating layer between the vertical semiconductor patterns and the stack structure,
the gate insulating layer including a blocking insulating layer and charge storing patterns,
the blocking insulating layer being adjacent to the stack structure, the charge storing patterns being spaced apart from the stack structure and arranged along a surface of the blocking insulating layer,
the blocking insulating layer between the charge storing patterns and the stack structure, and
wherein, as a distance to the blocking insulating layer decreases, widths of the charge storing patterns increase.

2. The device of claim 1, wherein the charge storing patterns have a polygonal shape, when viewed in a plan view or a sectional view.

3. The device of claim 1, wherein each of the charge storing patterns has a side surface that is inclined with respect to a surface of the blocking insulating layer.

4. The device of claim 1, wherein
each of the charge storing patterns comprises a first portion and a second portion,
the second portions are in contact with the blocking insulating layer and are connected to each other, and
the first portions are spaced apart from each other and spaced apart from the blocking insulating layer.

5. The device of claim 1, wherein
each of the electrode layers has a first vertical length,
each of the charge storing patterns has a second vertical length, and
the second vertical length is smaller than the first vertical length.

6. The device of claim 1, wherein each of the charge storing patterns is a doped silicon crystal pattern or an undoped silicon crystal pattern.

7. The device of claim 1, wherein
each of the vertical semiconductor patterns has silicon crystal grains, and
a mean size of the silicon crystal grains is larger than a mean size of the charge storing patterns.

8. The device of claim 1, wherein
the gate insulating layer further comprises a passivation layer,
the passivation layer is between the charge storing patterns and the vertical semiconductor patterns, and
the passivation layer covers the charge storing patterns.

9. The device of claim 8, wherein
the passivation layer comprises at least one of SiN, SiO, SiON, or a metal oxide material, and
the passivation layer has a single-layered structure or a multi-layered structure.

10. The device of claim 8, wherein
the gate insulating layer further comprises a tunnel insulating layer between the passivation layer and the vertical semiconductor patterns.

11. The device of claim 1, further comprising:
a source structure between the substrate and the stack structure,
wherein the vertical semiconductor patterns are penetrate the source structure and extend into the substrate,
the gate insulating layer is below the source structure and between the vertical semiconductor patterns and the substrate,
the source structure penetrates the gate insulating layer and is in contact with the vertical semiconductor patterns,
the gate insulating layer further comprises dummy charge storing patterns below the source structure, and
as a distance to the blocking insulating layer decrease, widths of the dummy charge storing patterns increase.

12. The device of claim 1, wherein the gate insulating layer further comprises:
a capping layer covering the charge storing patterns;
a passivation layer covering the capping layer; and
a tunnel insulating layer covering the passivation layer.

13. A three-dimensional semiconductor memory device, comprising:
a peripheral circuit structure; and
a cell array structure on the peripheral circuit structure,
the cell array structure including a first substrate, a source structure on the first substrate, a stack structure on the first substrate, a planarization insulating layer, a plurality of vertical semiconductor patterns, bit line pads, and a gate insulating layer between the plurality of vertical semiconductor patterns and the stack structure,
the first substrate including a cell array region and a connection region disposed in a first direction,
the stack structure including electrode layers and electrode interlayer insulating layers alternately stacked on the first substrate,
the planarization insulating layer on the connection region and covering an end portion of the stack structure;
the plurality of vertical semiconductor patterns on the cell array region, the plurality of vertical semiconductor patterns penetrating the stack structure and the source structure, the plurality of vertical semiconductor patterns adjacent to the first substrate,
the bit line pads on the plurality of vertical semiconductor patterns, respectively,
wherein the gate insulating layer including a blocking insulating layer and charge storing patterns, the blocking insulating layer is adjacent to the stack structure,
the charge storing patterns are spaced apart from the stack structure and arranged along a surface of the blocking insulating layer, the blocking insulating layer is between the charge storing patterns and the stack structure, and
each of the vertical semiconductor patterns includes silicon crystal grains having a mean size that is larger than a mean size of the charge storing patterns.

14. The device of claim 13, wherein as a distance to the blocking insulating layer decreases, widths of the charge storing patterns increase.

15. The device of claim 13, wherein a mean size of the charge storing patterns ranges from 3 nm to 10 nm.

16. The device of claim 13, wherein
the gate insulating layer further comprises a passivation layer,
the passivation layer is between the charge storing patterns and the vertical semiconductor patterns, and the passivation layer covers the charge storing patterns.

17. The device of claim 16, wherein
the passivation layer comprises at least one of SiN, SiO, SiON, or a metal oxide material, and the passivation layer has a single-layered structure or a multi-layered structure.

18. The device of claim 16, wherein the gate insulating layer further comprises a tunnel insulating layer between the passivation layer and the vertical semiconductor patterns.

19. The device of claim 13, wherein the gate insulating layer further comprises:
a capping layer covering the charge storing patterns;
a passivation layer covering the capping layer; and
a tunnel insulating layer covering the passivation layer.

20. An electronic system, comprising:
a semiconductor device including a peripheral circuit structure, a cell array structure on the peripheral circuit structure, and an input/output pad electrically connected to the peripheral circuit structure,
the cell array structure including a stack structure on the substrate, vertical semiconductor patterns penetrating the stack structure and placed adjacent to the substrate, and a gate insulating layer between the vertical semiconductor patterns and the stack structure, the stack structure including electrode layers and electrode interlayer insulating layers alternately stacked on the substrate,
the gate insulating layer including a blocking insulating layer and charge storing patterns, the blocking insulating layer being adjacent to the stack structure, the charge storing patterns being spaced apart from the stack structure and arranged along a surface of the blocking insulating layer,
the blocking insulating layer between the charge storing patterns and the stack structure,
wherein as a distance to the blocking insulating layer decreases, widths of the charge storing patterns increase; and
a controller electrically connected to the semiconductor device through the input/output pad, the controller configured to control the semiconductor device.

21-25. (canceled)
